(19) United States
(12) Patent Application Publication
(10) Pub. No.: US 2025/0336424 A1
(43) Pub. Date: Oct. 30, 2025

(54) SEMICONDUCTOR MEMORY DEVICE

(71) Applicant: SK hynix Inc., Icheon-si Gyeonggi-do (KR)

(72) Inventors: Won Geun CHOI, Icheon-si Gyeonggi-do (KR); Jung Shik JANG, Icheon-si Gyeonggi-do (KR); Rho Gyu KWAK, Icheon-si Gyeonggi-do (KR)

(73) Assignee: SK hynix Inc., Icheon-si Gyeonggi-do (KR)

(21) Appl. No.: 18/924,711

(22) Filed: Oct. 23, 2024

(30) Foreign Application Priority Data
Apr. 25, 2024 (KR) 10-2024-0055435

(51) Int. Cl. G11C 5/06; H01L 23/00; H01L 23/522; H01L 23/528; H01L 25/18; H10B 41/10; H10B 41/27; H10B 41/41; H10B 43/10; H10B 43/27; H10B 43/40; H10B 80/00

(52) U.S. Cl. CPC G11C 5/063; H01L 23/5226; H01L 23/5283; H01L 25/18; H10B 41/10; H10B 41/27; H10B 41/41; H10B 43/10; H10B 43/27; H10B 43/40; H10B 80/00; H01L 24/08; H01L 2224/08145; H01L 2225/06544; H01L 2924/1443

(57) ABSTRACT

A semiconductor memory device includes a bit line array including a plurality of bit lines extending in a first direction, a plurality of source layers extending in a second direction crossing the plurality of bit lines, a plurality of gate stack structures arranged between the bit line array and the plurality of source layers, and a conductive via structure coupled to a corresponding bit line among the plurality of bit lines.

### CROSS-REFERENCE TO RELATED APPLICATION

The present application claims priority under 35 U.S.C. § 119(a) to Korean patent application number 10-2024-0055435 filed on Apr. 25, 2024, in the Korean Intellectual Property Office, the entire disclosure of which application is incorporated herein by reference.

### BACKGROUND

### 1. Technical Field

Various embodiments of the present disclosure generally relate to a semiconductor memory device and an electronic system including the semiconductor memory device, and more particularly, to a three-dimensional semiconductor memory device and an electronic system including the three-dimensional semiconductor memory device.

### 2. Related Art

Semiconductor memory devices are applicable to electronic devices in various fields such as automobiles, medical care, and data centers, as well as small electronic devices. Accordingly, an increasing demand for semiconductor memory devices exists.

A semiconductor memory device includes a memory cell array including a plurality of memory cells for storing data. Non-volatile memory devices may be divided into a two-dimensional semiconductor memory device including a two-dimensional memory cell array and a three-dimensional semiconductor memory device including a three-dimensional memory cell array.

A plurality of memory cells of the three-dimensional memory cell array may be arranged in three dimensions. Therefore, compared to the two-dimensional cell array including a plurality of memory cells arranged on a plane, the three-dimensional cell array is more advantageous for large-capacity semiconductor memory devices.

### SUMMARY

According to an embodiment, a semiconductor memory device may include a bit line array including a plurality of bit lines extending in a first direction, a plurality of source layers extending in a second direction crossing the plurality of bit lines, the plurality of source layers overlapping with the plurality of bit lines, a plurality of gate stack structures arranged in the first direction, the plurality of gate stack structures each including a plurality of conductive layers stacked and spaced apart from each other in a third direction, the third direction toward the plurality of source layers and away from the bit line array, a plurality of channel pillars extending in the third direction to pass through, respectively, the plurality of gate stack structures, a memory layer extending on a side wall of each of the plurality of channel pillars, respectively, an isolation structure disposed between neighboring gate stack structures among the plurality of gate stack structures, the isolation structure extending in the second direction, and a first conductive via structure disposed in the isolation structure, the first conductive via structure coupled to a corresponding bit line among the plurality of bit lines.

According to an embodiment, a semiconductor memory device may include a first bit line array including a plurality of first bit lines extending in a first direction, a second bit line array disposed over the first bit line array and including a plurality of second bit lines extending in the first direction, a plurality of first source layers disposed between the first bit line array and the second bit line array, extending in a second direction crossing the plurality of first bit lines, and arranged in the first direction, a plurality of second source layers disposed between the plurality of first source layers and the second bit line array, extending in the second direction, and arranged in the first direction, a first memory cell array disposed between the first bit line array and the plurality of first source layers, the first memory cell array connected to a plurality of first gate stack structures arranged in the first direction, a second memory cell array disposed between the second bit line array and the plurality of second source layers, the second memory cell array connected to a plurality of second gate stack structures arranged in the first direction, and a first conductive via structure including a first portion arranged between the plurality of first gate stack structures and a second portion arranged between the plurality of second gate stack structures, and coupling a pair of a first bit line among the plurality of first bit lines and a second bit line among the plurality of second bit lines.

### BRIEF DESCRIPTION OF THE DRAWINGS

FIG. 1 is a block diagram illustrating a semiconductor memory device according to an embodiment of the present disclosure;

FIG. 2A is a perspective view illustrating a semiconductor memory device according to an embodiment of the present disclosure;

FIG. 2B is a circuit diagram illustrating a second sub-peripheral circuit, a first sub-memory cell array, and a second sub-memory cell array shown in FIG. 2A;

FIG. 3 is a plan view illustrating a semiconductor memory device according to an embodiment of the present disclosure;

FIGS. 4A and 4B are cross-sectional views illustrating a semiconductor memory device shown in FIG. 3;

FIGS. 5A, 5B, and 5C are cross-sectional views illustrating a semiconductor memory device shown in FIG. 3;

FIG. 6 is a perspective view illustrating a bit line array and a first conductive via group of a semiconductor memory device according to an embodiment of the present disclosure;

FIG. 7 is a plan view illustrating a semiconductor memory device according to an embodiment of the present disclosure;

FIG. 8 is a perspective view illustrating a semiconductor memory device according to an embodiment of the present disclosure;

FIGS. 9A and 9B are cross-sectional views illustrating a semiconductor memory device shown in FIG. 8;

FIGS. 10, 12, 14, 16, and 19 are plan views illustrating manufacturing processes for providing a semiconductor memory device according to an embodiment of the present disclosure;

FIGS. 11A, 11B, 13A, 13B, 15A, 15B, 17, 18A, 18B, 20A, 20B, 21A, 21B, 21C, 21D, 21E, and 21F are cross-sectional diagrams illustrating manufacturing processes for providing a semiconductor memory device according to an embodiment of the present disclosure; and

FIG. 22 is a block diagram illustrating an electronic system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

According to various embodiments of the present disclosure, a semiconductor memory device capable of improving operating reliability may be provided.

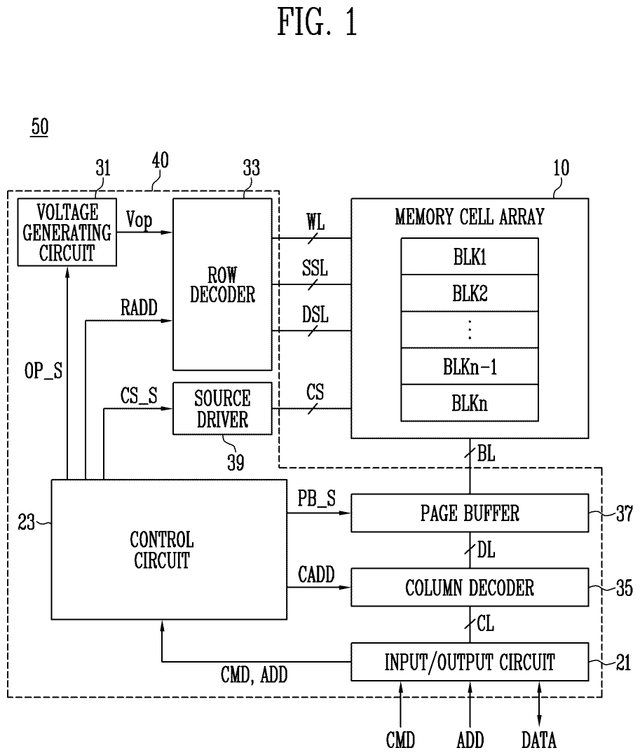

FIG. 1 is a block diagram illustrating a semiconductor memory device 50 according to an embodiment of the present disclosure.

Referring to FIG. 1, the semiconductor memory device 50 may include a peripheral circuit 40 and a memory cell array 10.

The peripheral circuit 40 may be configured to perform a program operation of storing data in the memory cell array 10, a read operation of outputting data stored in the memory cell array 10, and an erase operation of erasing data stored in the memory cell array 10. According to an embodiment, the peripheral circuit 40 may include an input/output circuit 21, a control circuit 23, a voltage generating circuit 31, a row decoder 33, a column decoder 35, a page buffer 37, and a source driver 39.

The peripheral circuit 40 may be coupled to the memory cell array 10 through a plurality of common source structures CS, a plurality of bit lines BL, a plurality of drain select lines DSL, a plurality of word lines WL, and a plurality of source select lines SSL.

The input/output circuit 21 may transfer a command CMD and an address ADD received from an external device (e.g., a memory controller) of the semiconductor memory device 50 to the control circuit 23. The input/output circuit 21 may exchange data DATA with the external device and the column decoder 35.

The control circuit 23 may output an operating signal OP_S, a row address RADD, a common source control signal CS_S a page buffer control signal PB_S, and a column address CADD in response to the command CMD and the address ADD.

The voltage generating circuit 31 may generate various operating voltages Vop applied to perform a program operation, a read operation, and an erase operation in response to the operating signal OP_S.

The row decoder 33 may transfer the operating voltages Vop to the plurality of drain select lines DSL, the plurality of word lines WL, and the plurality of source select lines SSL in response to the row address RADD.

The column decoder 35 may transfer the data DATA, which is input from the input/output circuit 21, to the page buffer 37, or may transfer the data DATA stored in the page buffer 37 to the input/output circuit 21 in response to the column address CADD. The column decoder 35 may exchange the data DATA with the input/output circuit 21 through the column line CL. The column decoder 35 may exchange the data DATA with the page buffer 37 through the data line DL.

The page buffer 37 may control the bit line BL in response to the page buffer control signal PB_S. During a program operation, the page buffer 37 may store the data DATA received from the column decoder 35 in response to the page buffer control signal PB_S and may apply voltages to the plurality of bit lines BL based on the stored data DATA. During a read operation, the page buffer 37 may sense voltages or currents of the bit lines BL and store sensing results in response to the page buffer control signal PB_S.

The source driver 39 may control a voltage or a bias applied to the common source structure CS, or may connect the common source structure CS in response to the common source control signal CS_S received from the control circuit 23.

The memory cell array 10 may include a plurality of memory blocks BLK1 to BLKn, where n is a natural number of 2 or more. The plurality of memory blocks BLK1 to BLKn may be coupled to the page buffer 37 through the plurality of bit lines BL. Each of the memory blocks may include a plurality of memory cell strings. Each memory block may be divided into a plurality of sub-blocks. Each sub-block may include a plurality of memory cells. The plurality of memory cells of each of the sub-blocks may be arranged in first to third directions different from each other to form a three-dimensional cell array. Each of the sub-blocks may include at least one source select line SSL, at least one drain select line DSL, and word lines WL stacked between at least one source select line SSL and at least one drain select line DSL. Some of the word lines WL of each sub-block may serve as dummy word lines. An erase operation may be controlled in units of common source structures CS. The common source structure CS may be coupled to the sub-block. At least one source layer may be coupled to the common source structure CS.

The memory cell array 10 of the semiconductor memory device 50 may overlap the peripheral circuit 40. The memory cell array 10 may be coupled to the peripheral circuit 40 through conductive via structures.

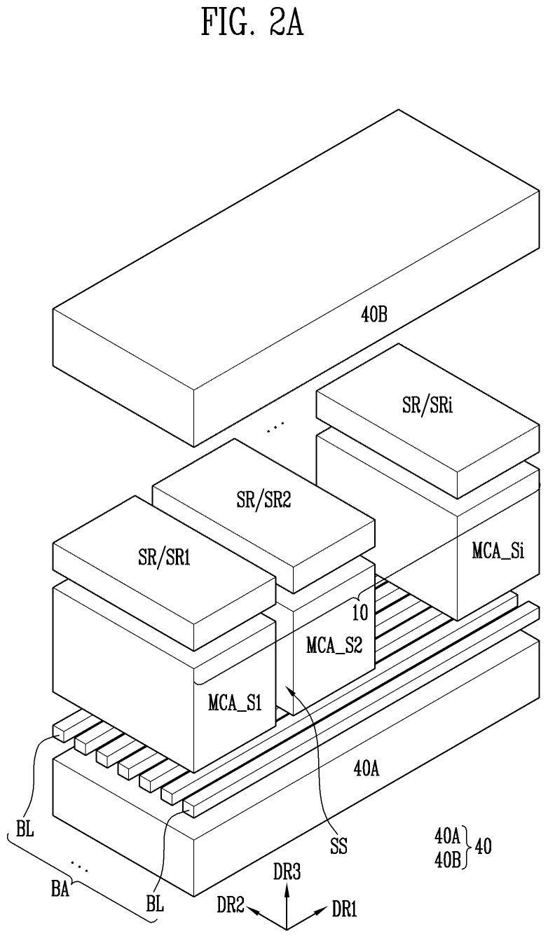

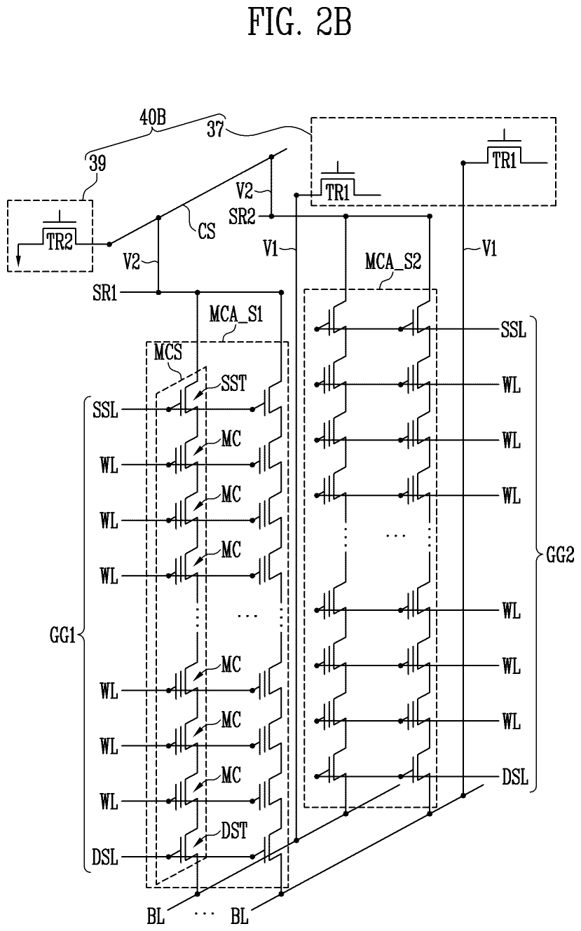

FIG. 2A is a perspective view illustrating a semiconductor memory device according to an embodiment of the present disclosure.

Referring to FIG. 2A, the peripheral circuit 40 may include a first sub-peripheral circuit 40A and a second sub-peripheral circuit 40B. The memory cell array 10 may be disposed between the first sub-peripheral circuit 40A and the second sub-peripheral circuit 40B and include a plurality of sub-memory cell arrays MCA_S1 to MCA_Si, where i is a natural number of 2 or more. A bit line array BA may include the plurality of bit lines BL and be disposed between the memory cell array 10 and the first sub-peripheral circuit 40A. A plurality of source layers SR may be arranged between the memory cell array 10 and the second sub-peripheral circuit 40B.

The plurality of bit lines BL may extend in a first direction DR1. The plurality of bit lines BL may be separated from each other in a second direction DR2.

The plurality of sub-memory cell arrays MCA_S1 to MCA_Si may be arranged in the first direction DR1. Sub-memory cell arrays which are adjacent to each other in the first direction DR1, for example, the sub-memory cell arrays MCA1_S1 and MCA_S2 may be divided from each other by an isolation structure SS. Each of the sub-memory cell arrays MCA_S1 to MCA_Si may include a plurality of sub-memory blocks. Each of memory blocks may include two or more sub-memory cell arrays. For example, a first memory block may include a first sub-memory cell array MCA_S1 and a second sub-memory cell array MCA_S2.

The plurality of source layers SR may overlap the bit line array BA and the memory cell array 10. The plurality of source layers SR may extend in the second direction DR2 to cross the plurality of bit lines BL. The plurality of source layers SR may be arranged in the first direction DR1. The plurality of source layers SR may correspond to the plurality of sub-memory cell arrays MCA_S1 to MCA_Si, respectively. According to an embodiment, the plurality of source layers SR may include a first source layer SR1 corresponding to the first sub-memory cell array MCA_S1, a second source layer SR2 corresponding to the second sub-memory cell array MCA_S2, and an ith source layer SRi corresponding to the ith sub-memory cell array MCA_Si. Each of the source layers SR may be arranged between a corresponding one of the plurality of sub-memory cell arrays and the second sub-peripheral circuit 40B.

Each of the source layers SR may include a semiconductor layer which includes at least one of an n-type impurity and a p-type impurity. According to an embodiment, the source layer SR may include a first conductivity type doped region which includes n type impurities as majority carriers. The first conductivity type doped region may be coupled to the common source structure. According to another embodiment, the source layer SR may further include a second conductivity type doped region which includes p type impurities as majority carriers.

The bit line array BA may be electrically coupled to the first sub-peripheral circuit 40A via of a first conductive via group. The first conductive via group may include a plurality of first conductive via structures corresponding to the plurality of bit lines BL, respectively. The plurality of first conductive via structures may extend in a third direction DR3 from the bit line array BA. The third direction DR3 may refer to a direction towards the plurality of source layers SR from the bit line array BA.

The plurality of source layers SR may be electrically coupled to the plurality of common source structures CS described above with reference to FIG. 1 via the second conductive via group. The second conductive via group may include a plurality of second conductive via structures coupled to each of the source layers SR.

FIG. 2B is a circuit diagram illustrating the second sub-peripheral circuit 40B, the first sub-memory cell array MCA_S1, and the second sub-memory cell array MCA_S2 shown in FIG. 2A.

Referring to FIG. 2B, the first sub-memory cell array MCA_S1 and the second sub-memory cell array MCA_S2 may be included in the same memory block.

The second sub-peripheral circuit 40B may include the page buffer 37 and the source driver 39. The page buffer 37 may include a plurality of first transistors TR1. The source driver 39 may include a second transistor TR2. The plurality of first transistors TR1 may be connected to the plurality of bit lines BL of a corresponding memory block, respectively. The second transistor TR2 may be connected to the common source structure CS corresponding thereto.

Each of the first sub-memory cell array MCA_S1 and the second sub-memory cell array MCA_S2 may include a plurality of memory cell strings MCS. Each of the memory cell strings MCS may include one drain select transistor DST, a plurality of memory cells MC, and at least one source select transistor SST. The plurality of memory cells MC in each of the memory cell strings MCS may be stacked between the drain select transistor DST and the source select transistor SST.

The memory cell string of the first sub-memory cell array MCA_S1 and the memory cell string of the second sub-memory cell array MCA_S2 of each bit line BL may be electrically coupled to each other. The bit line BL may be electrically coupled to the corresponding first transistor TR1 via a first conductive via structure V1.

The plurality of memory cell strings MCS of the first sub-memory cell array MCA_S1 may be electrically coupled to the first source layer SR1. The plurality of memory cell strings MCS of the second sub-memory cell array MCA_S2 may be electrically coupled to the second source layer SR2. Each of the first source layer SR1 and the second source layer SR2 may be electrically coupled to the common source structure CS via a second conductive via structure V2 corresponding thereto.

The first sub-memory cell array MCA_S1 may be coupled to a first gate group GG1. The second sub-memory cell array MCA_S2 may be coupled to a second gate group GG2. Each of the first gate group GG1 and the second gate group GG2 may include at least one drain select line DSL, the plurality of word lines WL, and at least one source select line SSL. In each gate group (GG1 or GG2), the plurality of word lines WL may be stacked between the drain select line DSL and the source select line SSL. In each gate group (GG1 or GG2), the drain select line DSL may be coupled to a gate electrode of the drain select transistor DST, the plurality of word lines WL may be coupled to a plurality of gate electrodes of the plurality of memory cells MC, and the plurality of source select lines SSL may be coupled to a gate electrode of the source select transistor SST. Each of the first gate group GG1 and the second gate group GG2 may include conductive layers of a gate stack structure corresponding thereto.

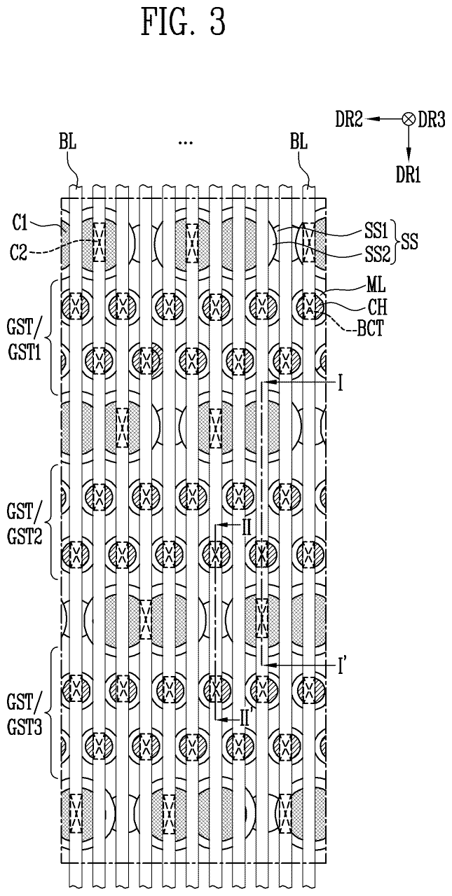

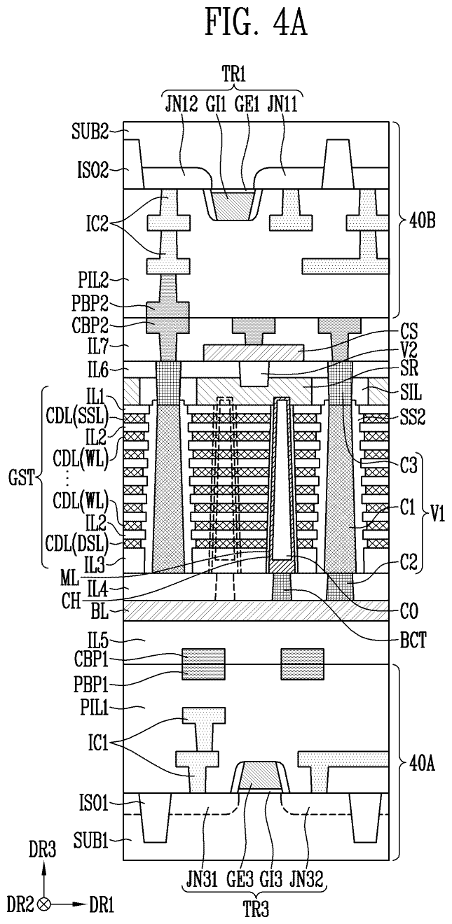

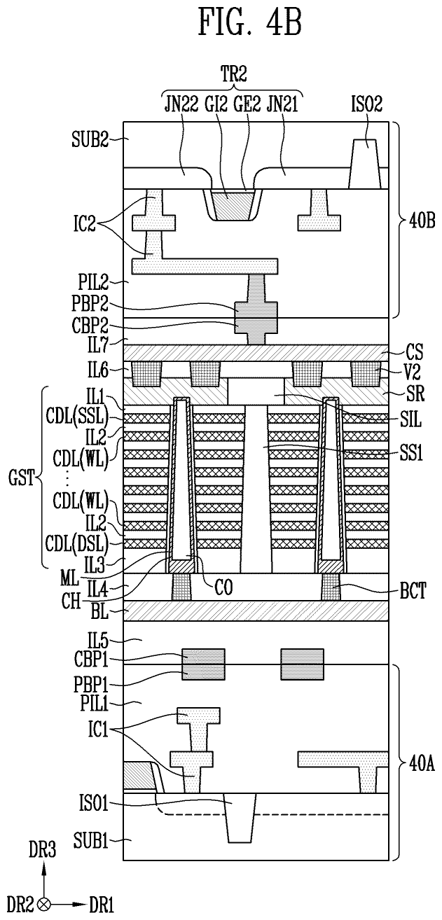

FIG. 3 is a plan view illustrating a semiconductor memory device according to an embodiment of the present disclosure. FIGS. 4A and 4B are cross-sectional views illustrating a semiconductor memory device shown in FIG. 3. FIG. 4A shows a cross section of the semiconductor memory device taken along line I-I′ of FIG. 3. FIG. 4B shows a cross section of the semiconductor memory device taken along line II-II′.

Referring to FIGS. 3, 4A, and 4B, as described above with reference to FIG. 2A, the plurality of bit lines BL may extend in the first direction DR1 and be spaced apart from each other in the second direction DR2. As described above with reference to FIG. 2A, the plurality of source layers SR may be arranged in the first direction DR1.

The plurality of gate stack structures GST may be disposed between the plurality of bit lines BL and the plurality of source layers SR and may be arranged in the first direction DR1. The plurality of gate stack structures GST may correspond to the plurality of source layers SR, respectively. Each of the gate stack structures GST may be arranged between the source layer SR corresponding thereto and the plurality of bit lines BL.

The isolation structure SS may be arranged between neighboring gate stack structures in the first direction DR1 (e.g., between GST1 and GST2 or between GST2 and GST3). The isolation structure SS may be arranged alternately with the gate stack structure GST in the first direction DR1. The neighboring gate stack structures in the first direction DR1 may be spaced apart from each other by the isolation structure SS. The isolation structure SS may extend in the second direction DR2 and overlap the plurality of bit lines BL.

A source isolation insulating layer SIL may be disposed between neighboring source layers SR in the first direction DR1. The source isolation insulating layer SIL may be arranged alternately with the source layer SR in the first direction DR1. The source isolation insulating layer SIL may separate the neighboring source layers SR in the first direction DR1 from each other. The source isolation insulating layer SIL may overlap the isolation structure SS. The source isolation insulating layer SIL may extend in the second direction DR2.

Each of the gate stack structures GST may include a first insulating layer IL1, a plurality of second insulating layers IL2, a plurality of conductive layers CDL, and a third insulating layers IL3. The first insulating layer IL1 may be arranged adjacent to the source layer SR. The third insulating layer IL3 may be arranged adjacent to the bit line BL. The plurality of second insulating layers IL2 and the plurality of conductive layers CDL may be disposed between the first insulating layer IL1 and the third insulating layer IL3. The second insulating layer IL2 may be arranged alternately with the conductive layer CDL in the third direction DR3. The plurality of conductive layers CDL may be spaced apart from each other in the third direction DR3 by the plurality of second insulating layers IL2. However, embodiments of the present disclosure are not limited thereto. According to an embodiment, the plurality of conductive layers CDL may be separated from each other by an air-gap therebetween. The air-gap includes a hollow space, generally encapsulating vacuum, gas or air.

Among the conductive layers CDL, at least one conductive layer CDL may serve as the source select line SSL (i.e., CDL(SSL)), at least one conductive layer CDL may serve as the drain select line DSL (i.e., CDL(DSL)), and the other conductive layers CDL may serve as the word lines WL (i.e., CDL(WL)). Each of the conductive layers CDL may include various conductive materials such as a doped semiconductor layer, a metal layer, and the like. The doped semiconductor layer may include a doped silicon layer. The metal layer may include tungsten, copper, molybdenum, or the like. Each of the conductive layers CDL may further include a conductive metal nitride layer which is provided as a barrier layer. The conductive metal nitride layer may include a tantalum nitride, a tantalum nitride, or the like. The first insulating layer IL1, the plurality of second insulating layers IL2 and the third insulating layer IL3 may include an insulating material such as a silicon oxide (SiOx) layer and a silicon oxynitride (SiON) layer.

Each of the gate stack structures GST may be penetrated by a plurality of channel pillars CH. The memory cell string MCS as described above with reference to FIG. 2 may be formed along each of the channel pillars CH. Each of the channel pillars CH may extend in the third direction DR3 to pass through the first insulating layer IL1, the plurality of second insulating layers IL2, the plurality of conductive layers CDL, and the third insulating layer IL3 of the gate stack structure GST corresponding thereto. The channel pillar CH may include a semiconductor material which serves as a channel region of the memory cell string. The semiconductor material may include silicon (Si), germanium (Ge), or a mixture thereof. The channel pillar CH may have various structures. According to an embodiment, a central area of the channel pillar CH may be filled with a core insulating layer CO. Each of end portions of the channel pillar CH adjacent to the bit line BL and the source layer SR may include at least one of an n type impurity and a p type impurity. According to an embodiment, each of the end portions of the channel pillar CH adjacent to the bit line BL and the source layer SR may be configured as an n-type impurity region including the n type impurity as majority carriers.

The semiconductor memory device may further include a memory layer ML which extends on a side wall of the channel pillar CH. The memory layer ML may be interposed between the channel pillar CH and the gate stack structure GST.

One end of the channel pillar CH may extend into the source layer SR to come into contact with the source layer SR corresponding thereto. The channel pillar CH may include a contact surface which contacts the source layer SR. The contact surface may be defined between one end of the channel pillar CH and the source layer SR. According to an embodiment, the channel pillar CH may protrude toward the source layer SR corresponding thereto more than the memory layer ML, and the source layer SR may include a groove into which the one end of the channel pillar CH is inserted. The contact surface between the source layer SR and the channel pillar CH may be defined along the groove of the source layer SR.

The plurality of channel pillars CH may be coupled to a plurality of bit line contacts BCT, respectively. Each of the bit line contacts BCT may couple the channel pillar CH to the bit line BL. The bit line contacts BCT may pass through a fourth insulating layer IL4 which is interposed between the gate stack structure GST and the bit line BL.

Each of the bit lines BL may be coupled to the first conductive via structure V1 corresponding thereto. The first conductive via structure V1 may include a first contact pattern C1, a second contact pattern C2, and a third contact pattern C3. The first contact pattern C1 may include a conductive material which is disposed in the isolation structure SS. The second contact pattern C2 may include a conductive material which passes through the fourth insulating layer IL4. The third contact pattern C3 may include a conductive material which passes through the source isolation insulating layer SIL. The first contact pattern C1 may be aligned with the second contact pattern C2 in the third direction DR3 and be coupled to the second contact pattern C2. The third contact pattern C3 may be aligned with the first contact pattern C1 in the third direction DR3 and be coupled to the first contact pattern C1.

The isolation structure SS may include a plurality of first insulating structures SS1 and a plurality of second insulating structures SS2 which are arranged in the second direction DR2. The plurality of first insulating structures SS1 may be spaced apart from each other in the second direction DR2. Each of the second insulating structures SS2 may be arranged between neighboring first insulating structures SS1 in the second direction DR2. The second insulating structure SS2 may surround a side wall of the first contact pattern C1 of the first conductive via structure V1. The first contact pattern C1 may be separated from the gate stack structure GST by the second insulating structure SS2.

The bit line BL may include one side toward the gate stack structure GST and the other side opposite to the one side. The other side of the bit line BL may be covered by a fifth insulating layer IL5. The fifth insulating layer IL5 may include at least two insulating layers. A first cell-side bonding pattern CBP1 may be arranged in the fifth insulating layer IL5.

The plurality of source layers SR may be covered by a sixth insulating layer IL6. A common source structure CS may be arranged above the sixth insulating layer IL6. The common source structure CS may have various structures such as a line type, a mesh type, a flat type, and the like. The common source structure CS may include a conductive material including metal. The common source structure CS may be coupled to the plurality of source layers SR via a plurality of second conductive via structures V2. The plurality of second conductive via structures V2 may pass through the sixth insulating layer IL6.

The common source structure CS may be covered by a seventh insulating layer IL7. The seventh insulating layer IL7 may include at least two insulating layers. Second cell-side bonding patterns CBP2 may be arranged in the seventh insulating layer IL7. The second cell-side bonding patterns CBP2 may include a bonding pattern connected to the third contact pattern C3 of the first conductive via structure V1 and a bonding pattern connected to the common source structure CS.

The first cell-side bonding pattern CBP1 may be bonded to a first peripheral circuit-side bonding pattern PBP1 of the first sub-peripheral circuit 40A. The second cell-side bonding patterns CBP2 may be bonded to second peripheral circuit-side bonding patterns PBP2 of the second sub-peripheral circuit 40B. Each of the first cell-side bonding pattern CBP1, the second cell-side bonding patterns CBP2, the first peripheral circuit-side bonding pattern PBP1, and the second peripheral circuit-side bonding patterns PBP2 may include a bonding metal such as copper, aluminum, and tungsten.

The second sub-peripheral circuit 40B may include the first transistor TR1 and the second transistor TR2 as described above with reference to FIG. 2B. The first sub-peripheral circuit 40A may include a third transistor TR3. According to an embodiment, the third transistor TR3 may be one of the pass transistors which constitute the row decoder 33 shown in FIG. 1.

The third transistor TR3 of the first sub-peripheral circuit 40A may be covered by a first peripheral circuit insulating structure PIL1 between a first semiconductor substrate SUB1 and the fifth insulating layer IL5. The third transistor TR3 may be disposed in an active region of the first semiconductor substrate SUB1 which is divided by a first isolation layer IS01.

The first transistor TR1 and the second transistor TR2 of the second sub-peripheral circuit 40B may be covered by a second peripheral circuit insulating structure PIL2 between a second semiconductor substrate SUB2 and the seventh insulating layer IL7. The first transistor TR1 and the second transistor TR2 may be disposed in active regions of the second semiconductor substrate SUB2 divided by a second isolation layer IS02.

Each of the first transistor TR1, the second transistor TR2, and the third transistor TR3 may include a gate insulating layer (GI1, GI2, or GI3), a gate electrode (GE1, GE2, or GE3), a first junction (JN11, JN21, or JN31), and a second junction (JN21, JN22, or JN32). The gate insulating layer GI1, G12, or G13 and the gate electrode GE1, GE2, or GE3 may be stacked on an active region of the semiconductor substrate SUB1 or SUB2 corresponding thereto. The first junction JN11, JN21, or JN31, and the second junction JN21, JN22, or JN32 may be arranged in the semiconductor substrate SUB1 or SUB2 corresponding thereto and may serve as a source region and a drain region.

The third transistor TR3 may be coupled to first interconnections IC1 which are disposed in the first peripheral circuit insulating structure PIL1. The first transistor TR1 and the second transistor TR2 may be coupled to second interconnections IC2 which are disposed in the second peripheral circuit insulating structure PIL2. Some of the second interconnections IC2 may be used to couple the second junction JN12 of the first transistor TR1 to one of the second cell-side bonding patterns CBP2. Other second interconnections IC2 may be used to couple the second junction JN22 to another cell-side bonding pattern CBP2.

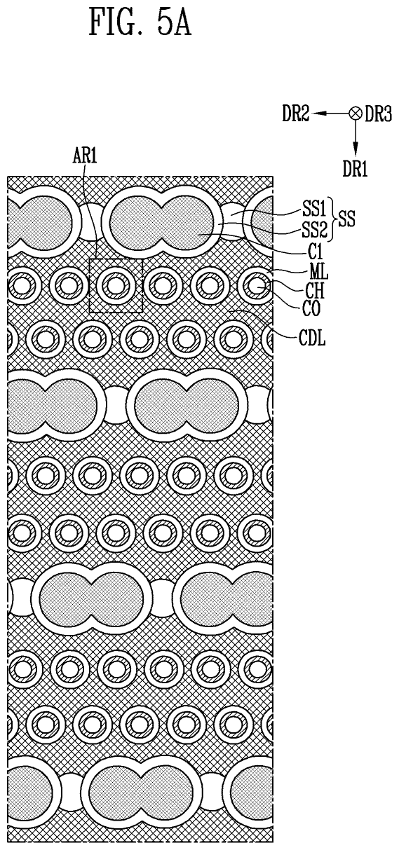

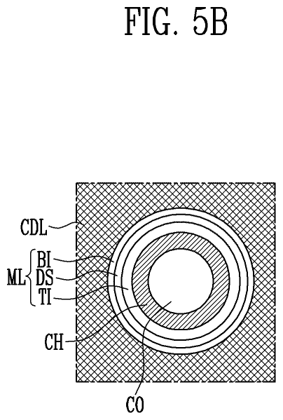

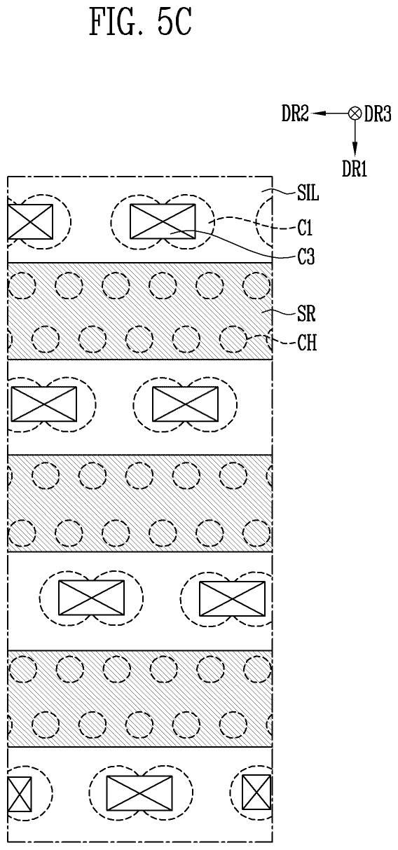

FIGS. 5A, 5B, and 5C are plan views illustrating a semiconductor memory device shown in FIG. 3.

FIG. 5A is a plan view of a semiconductor memory device in a level where the conductive layer CDL shown in FIG. 3 is disposed. FIG. 5B is an enlarged plan view of an area “AR1” shown in FIG. 5A.

Referring to FIGS. 5A and 5B, the conductive layer CDL may extend in the first direction DR1 and the second direction DR2 to surround a side wall of the channel pillar CH. The core insulating layer CO may be disposed in a central area of the channel pillar CH. The memory layer ML may be interposed between the channel pillar CH and the conductive layer CDL.

The memory layer ML may include a tunnel isolation layer TI, a data storage layer DS, and a blocking insulating layer BI. The tunnel isolation layer TI may extend in the third direction DR3 on an outer wall of the channel pillar CH. The tunnel isolation layer TI may include an insulating material such as a silicon oxide layer. The data storage layer DS may be interposed between the conductive layer CDL and the tunnel isolation layer TI. According to an embodiment, the data storage layer DS may continuously extend in the third direction DR3 on an outer wall of the tunnel isolation layer TI. According to another embodiment, the data storage layer DS may be separated into a plurality of data storage patterns which are spaced apart from each other in the third direction DR3, and each of the data storage patterns may be disposed between the conductive layer CDL and the channel pillar CH corresponding thereto. The data storage layer DS may include a material layer capable of storing varying data using Fowler-Nordheim tunneling. According to an embodiment, the data storage layer DS may include a charge trap insulating layer, a floating gate layer, or an insulating layer including conductive nanodots. The charge trap insulating layer may include a silicon nitride layer. The blocking insulating layer BI may be interposed between the conductive layer CDL and the data storage layer DS. The blocking insulating layer BI may include any one of a silicon dioxide (SiO₂) layer and a high dielectric layer having a greater dielectric constant than the silicon dioxide layer. The high dielectric layer may include an aluminum oxide layer, a hafnium oxide layer, or the like.

The first insulating structure SS1 and the second insulating structure SS2 may be arranged alternately with each other in the second direction DR2 to form rows. The second insulating structure SS2 may surround a side wall of the first contact pattern C1 of the first conductive via structure V1.

FIG. 5C is a plan view illustrating a semiconductor memory device in a level where the source layer SR shown in FIG. 3 is arranged.

Referring to FIG. 5C, the source layer SR may be arranged alternately with the source isolation insulating layer SIL in the first direction DR1. The source layer SR may overlap the plurality of channel pillars CH.

The source isolation insulating layer SIL may be penetrated by the third contact pattern C3 of the first conductive via structure. The third contact pattern C3 may overlap the first contact pattern C1 of the first conductive via structure V1.

As described above with reference to FIGS. 3, 4A, 4B, 5A, 5B, and 5C, the first conductive via structure V1 coupled to the bit line BL may be disposed between neighboring gate stack structures GST. Accordingly, in an embodiment, a degree of integration of a semiconductor memory device may be increased beacuse it is not necessary to provide a separate area for the first conductive via structure V1 for coupling the bit line BL to the first transistor TR1. In addition, in an embodiment, because the connection structure between the bit line BL and the first transistor TR1 is simplified, structural defects occurring during manufacturing processes of the semiconductor memory device may be reduced.

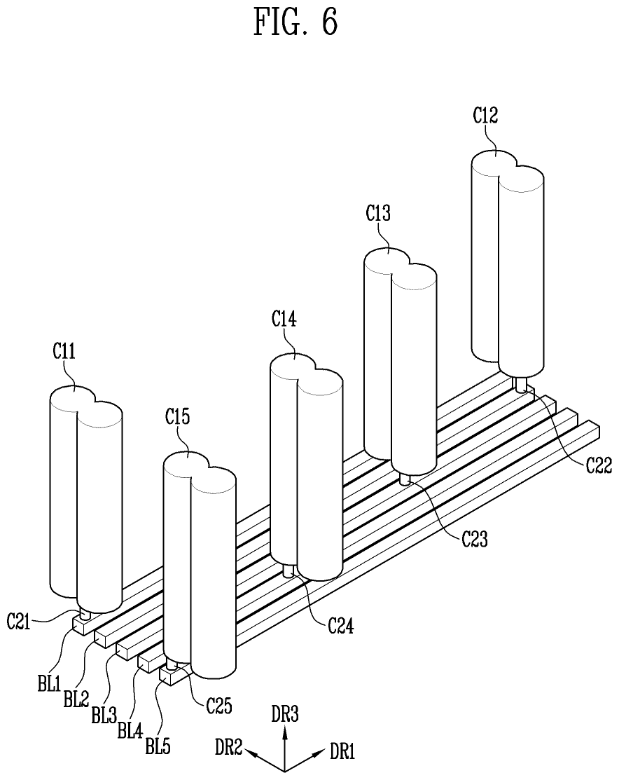

FIG. 6 is a perspective view illustrating a bit line array and a first conductive via group of a semiconductor memory device according to an embodiment of the present disclosure.

According to embodiments of the present disclosure, the first conductive via group may include a plurality of first conductive via structures corresponding to a plurality of bit lines, and each of the first conductive via groups may include a first contact pattern and a second contact pattern corresponding thereto. The plurality of first contact patterns of the plurality of first conductive via structures may overlap bit lines corresponding thereto and be spaced apart from each other in the first direction DR1 and the second direction DR2. Each of the plurality of second contact patterns of the plurality of the first conductive via structures may be disposed between a bit line and a first contact pattern corresponding thereto.

Referring to FIG. 6, according to an embodiment, a plurality of bit lines may include first to fifth bit lines BL1 to BL5 which are spaced apart from each other in the second direction DR2. The first to fifth bit lines BL1 to BL5 may be coupled to different first conductive via structures. In an embodiment, each of the first contact patterns C11, C12, C13, C14, and C15 may overlap a bit line corresponding thereto among the first to fifth bit lines BL1 to BL5 and have a greater width than each bit line in the second direction DR2. As a result, in an embodiment, misalignment errors between each of the first contact patterns C11, C12, C13, C14, and C15 and the bit line corresponding thereto may be reduced. In an embodiment, each of the second contact patterns C21, C22, C23, C24, and C25 of the first conductive via structures may couple a corresponding one of the bit lines and a corresponding one of the first contact patterns in an area where the bit line and the first contact pattern overlap each other.

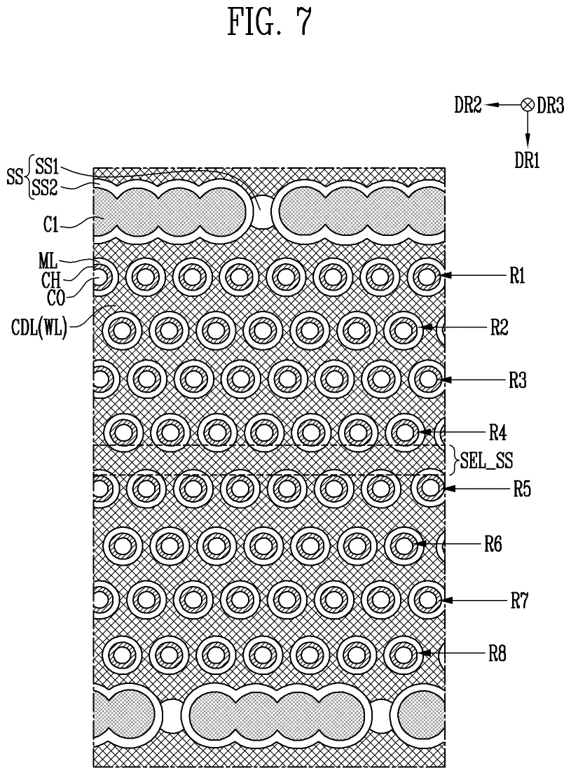

FIG. 7 is a plan view illustrating a semiconductor memory device according to an embodiment of the present disclosure.

Referring to FIG. 7, the conductive layer CDL serving as the word line WL (i.e., CDL(WL)) may be penetrated by the plurality of channel pillars CH, and the plurality of channel pillars CH may form at least one row. Each row may be composed of the channel pillars CH arranged in a line. According to an embodiment, the plurality of channel pillars CH may be arranged in first to eighth rows R1 to R8. When the channel pillars CH passing through each word line WL are arranged in four or more rows, at least one of a drain select gate layer and a source select gate layer overlapping each word line WL may be separated into two or more select lines on the same layer by a select line isolation structure SEL_SS. Though not shown in FIG. 7, dummy pillars may be arranged along the select line isolation structure SEL_SS. Each of the dummy pillars may include a dummy channel pillar having a similar structure to the channel pillar CH, a dummy core insulating layer having a similar structure to the core insulating layer CO, and a dummy memory layer having a similar structure to the memory layer ML.

Referring to FIGS. 5A and 7, the second insulating structure SS2 of the isolation structure SS and the first contact pattern C1 of the first conductive via structure may extend in the second direction DR2 more than the first insulating structure SS1 of the isolation structure SS. In various embodiments, the second insulating structure SS2 of the isolation structure SS and the first contact pattern C1 of the first conductive via structure may be designed to have various lengths. In various embodiments, the second insulating structure SS2 of the isolation structure SS and the first contact pattern C1 of the first conductive via structure may have uneven side walls.

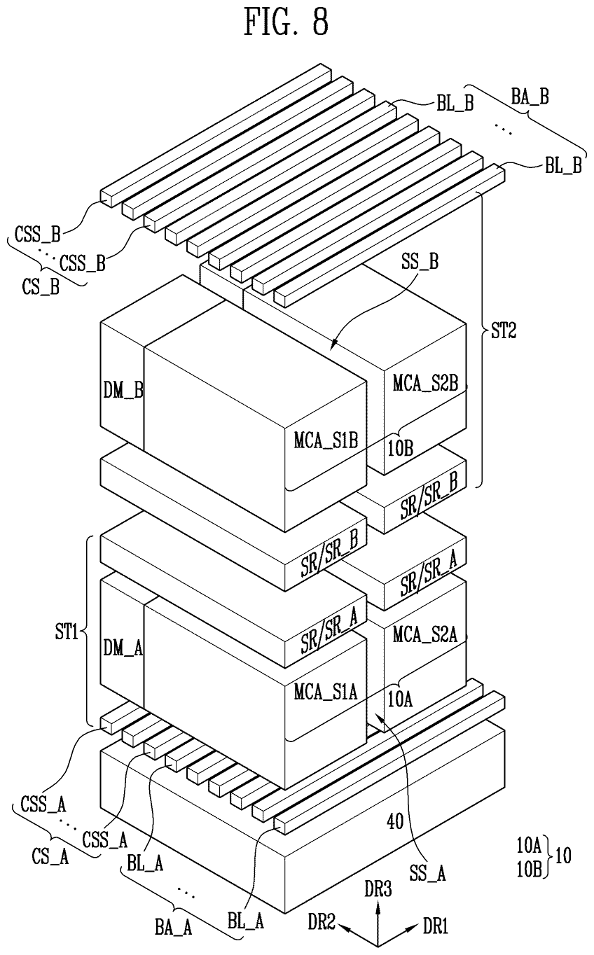

FIG. 8 is a perspective view illustrating a semiconductor memory device according to an embodiment of the present disclosure.

Referring to FIG. 8, the memory cell array 10 may include a first memory cell array 10A and a second memory cell array 10B. A plurality of bit lines may include a plurality of first bit lines BL_A of a first bit line array BA_A and a plurality of second bit lines BL_B of a second bit line array BA_B. The plurality of source layers SR may include a plurality of first source layers SR_A and a plurality of second source layers SR_B. As described above with reference to FIG. 2A, each of the source layers SR may include a semiconductor layer which includes at least one of an n type impurity and a p type impurity.

The first memory cell array 10A, the first bit line array BA_A, and the plurality of first source layers SR_A may constitute a first structure ST1. The second memory cell array 10B, the second bit line array BA_B, and the plurality of second source layers SR_B may constitute a second structure ST2.

The first bit line array BA_A of the first structure ST1 may be disposed over the peripheral circuit 40. The plurality of first bit lines BL_A may extend in the first direction DR1 and be spaced apart from each other in the second direction DR2. The second bit line array BA_B of the second structure ST2 may be disposed over the first structure ST1. The plurality of first bit lines BL_A may extend in the first direction DR1 and be spaced apart from each other in the second direction DR2.

The plurality of first source layers SR_A of the first structure ST1 may be disposed between the first bit line array BA_A and the second bit line array BA_B. The plurality of first source layers SR_A may extend in the second direction DR2 to cross the plurality of first bit lines BL_A and may be spaced apart from each other in the first direction DR1.

The plurality of second source layers SR_B of the second structure ST2 may be disposed between the plurality of first source layers SR_A and the second bit line array BA_B. The plurality of first source layers SR_B may extend in the second direction DR2 to cross the plurality of second bit lines BL_B and may be spaced apart from each other in the first direction DR1.

The first memory cell array 10A of the first structure ST1 may be disposed between the first bit line array BA_A and the plurality of first source layers SR_A. The first memory cell array 10A may include a plurality of first sub-memory cell arrays MCA_S1A and MCA_S2A which are arranged in the first direction DR1. The first sub-memory cell arrays MCA_S1A and MCA_S2A adjacent to each other may be divided by a first isolation structure SS_A. The first structure ST1 may further include a first dummy memory cell array DM_A and a first common source structure CS_A which is disposed between the first dummy memory cell array DM_A and the peripheral circuit 40. The first common source structure CS_A may be spaced apart from the first bit line array BA_A in the second direction DR2. The first common source structure CS_A may include a plurality of first sub-source structures CSS_A. The plurality of first sub-source structures CSS_A may extend in the first direction DR1 and be spaced apart from each other in the second direction DR2. Though not shown, the first common source structure CS_A may further include a first connection structure which couples the plurality of first sub-source structures CSS_A to each other.

The second memory cell array 10B of the second structure ST2 may be disposed between the second bit line array BA_B and the plurality of second source layers SR_B. The second memory cell array 10B may include a plurality of second sub-memory cell arrays MCA_S1B and MCA_S2B which are arranged in the first direction DR1. Neighboring second sub-memory cell arrays MCA_S1B and MCA_S2B may be divided by a second isolation structure SS_B. The second structure ST2 may further include a second dummy memory cell array DM_B and a second common source structure CS_B which is disposed over the second dummy memory cell array DM_B. The second common source structure CS_B may be spaced apart from the second bit line array BA_B in the second direction DR2. The second common source structure CS_B may include a plurality of second sub-source structures CSS_B. The plurality of second sub-source structures CSS_B may extend in the first direction DR1 and be spaced apart from each other in the second direction DR2. Though not shown, the second common source structure CS_B may further include a second connection structure which couples the plurality of second sub-source structures CSS_B to each other.

The first bit line array BA_A may be electrically coupled to the second bit line array BA_B through the first conductive via group. The first common source structure CSS_A, the plurality of first source layers SR_A, the plurality of second source layers SR_B, and the second common source structure CSS_B may be electrically coupled to each other through the second conductive via group. The first conductive via group may include a first conductive via structure which extends into the second isolation structure SS_B from the inside of the first isolation structure SS_A. The second conductive via group may include a second conductive via structure which extends into the second isolation structure SS_B from the inside of the first isolation structure SS_A.

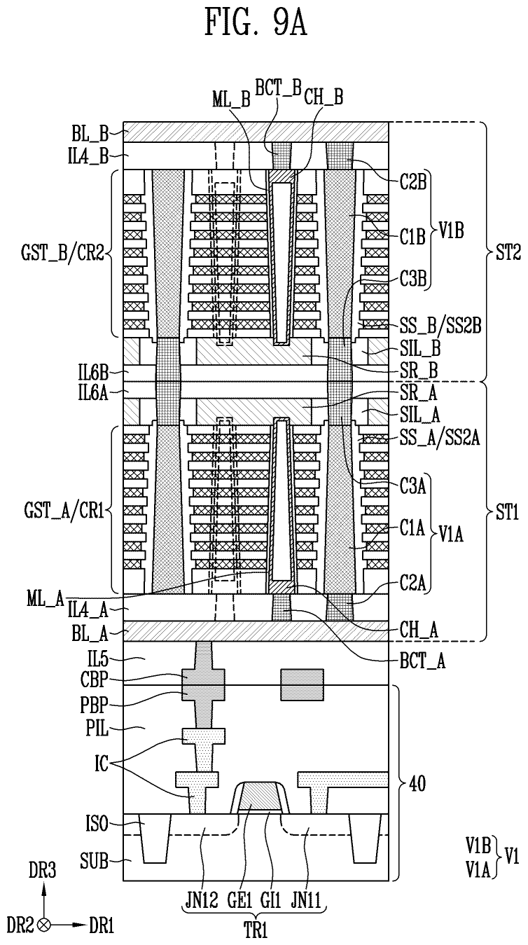

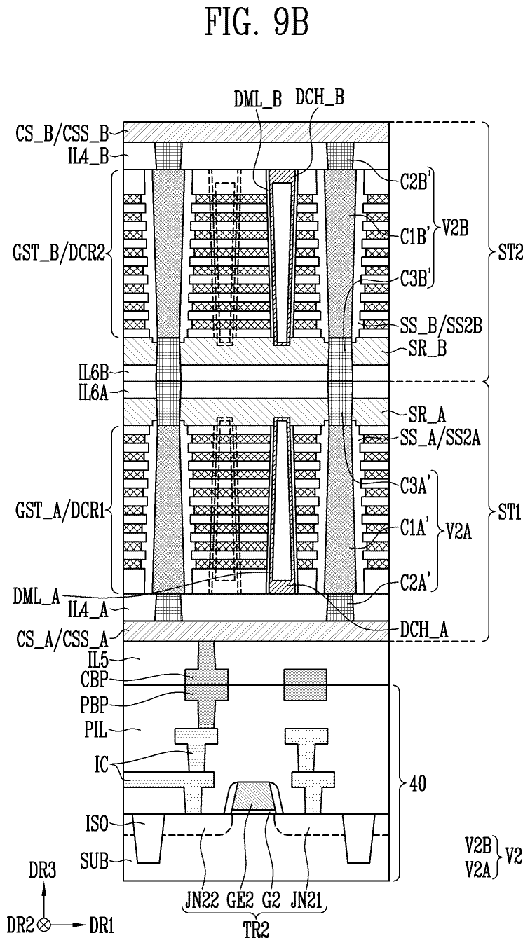

FIGS. 9A and 9B are cross-sectional views illustrating the semiconductor memory device shown in FIG. 8. FIG. 9A shows a cross section of a semiconductor memory device taken along line the first bit line BL_A or the second bit line BL_B. FIG. 9B shows a cross section of the semiconductor memory device taken along the first sub-source structure CSS_A of the first common source structure CS_A or the second sub-source structure CSS_B of the second common source structure CS_B.

Referring to FIGS. 8, 9A, and 9B, the first structure ST1 may include a plurality of first gate stack structures GST_A, the first bit line BL_A, and the plurality of first source layers SR_A which are coupled to the plurality of first memory cell arrays 10A. The second structure ST2 may include a plurality of second gate stack structures GST_B, the second bit line BL_B, and the plurality of second source layers SR_B which are coupled to the plurality of second memory cell arrays 10B.

Referring to FIGS. 9A and 9B, the plurality of first gate stack structures GST_A may be arranged in the first direction DR1 between the first bit line BL_A and the plurality of first source layers SR_A. Each of the first gate stack structures GST_A may be arranged between the first source layer SR_A and the first bit line BL_A corresponding thereto. The first gate stack structure GST_A and the first source layer SR_A may extend to overlap the first common source structure CS_A. Hereinafter, a portion of the first gate stack structure GST_A disposed between the first source layer SR_A and the first bit line BL_A is referred to as a first cell array region CR1 (i.e., GST_A/CR1), and another portion thereof disposed between the first source layer SR_A and the first common source structure CS_A is referred to as a first dummy cell region DCR1 (i.e., GST_A/DCR1).

The plurality of second gate stack structures GST_B may be arranged in the first direction DR1 between the second bit line BL_B and the plurality of second source layers SR_B. Each of the second gate stack structures GST_B may be arranged between the second source layer SR_B and the second bit line BL_B corresponding thereto. The second gate stack structure GST_B and the second source layer SR_B may extend to overlap the second common source structure CS_B. Hereinafter, a portion of the second gate stack structure GST_B disposed between the second source layer SR_B and the second bit line BL_B is referred to as a second cell array region CR2 (i.e., GST_B/CR2), and another portion thereof disposed between the second source layer SR_B and the second common source structure CS_B is referred to as a second dummy cell region DCR2 (i.e., GST_B/DCR2).

As in the gate stack structure GST described above with reference to FIGS. 4A and 4B, each of the first gate stack structures GST_A and the plurality of second gate stack structures GST_B may include a first insulating layer, a plurality of conductive layers, a plurality of insulating layers, and a third insulating layer.

Referring to FIGS. 8, 9A, and 9B, the first sub-memory cell array MCA_S1A or MCA_S2A of the first memory cell array 10A may be connected to a plurality of conductive layers of the first gate stack structure GST_A corresponding thereto. The second sub-memory cell array MCA_S1B or MCA_S2B of the second memory cell array 10B may be connected to a plurality of conductive layers of the second gate stack structure GST_B corresponding thereto.

Referring to FIGS. 9A and 9B, each of the first sub-memory cell arrays may include a first channel pillar CH_A connected to the first source layer SR_A and the first bit line BL_A corresponding thereto, and a first memory layer ML_A extending on a side wall of the first channel pillar CH_A. Each of the second memory cell arrays may include a second channel pillar CH_B connected to the second source layer SR_B and the second bit line BL_B corresponding thereto, and a second memory layer ML_B extending on a side wall of the second channel pillar CH_B.

Referring to FIGS. 8, 9A, and 9B, the first dummy memory cell array DM_A may include a first dummy channel pillar DCH_A which passes through a first dummy cell array region DCR1 of the first gate stack structure GST_A, and a first dummy memory layer DML_A which extends on a side wall of the first dummy channel pillar DCH_A. The second dummy memory cell array DM_B may include a second dummy channel pillar DCH_B which passes through a second dummy cell array region DCR2 of the second gate stack structure GST_B, and a second dummy memory layer DML_B which extends on a side wall of the second dummy channel pillar DCH_B.

Referring to FIGS. 9A and 9B, each of the first channel pillar CH_A, the second channel pillar CH_B, the first dummy channel pillar DCH_A, and the second dummy channel pillar DCH_B may have the same configuration as the channel pillar CH shown in FIGS. 4A and 4B. Each of the first memory layer ML_A, the second memory layer ML_B, the first dummy memory layer DML_A, and the second dummy memory layer DML_B may have the same configuration as the memory layer ML shown in FIG. 5B.

The first channel pillar CH_A may pass through the first cell array region CR1 of the first gate stack structure GST_A to directly contact the first source layer SR_A, and may be connected to the first bit line BL_A via a first bit line contact BCT_A. The second channel pillar CH_B may pass through the second cell array region CR2 of the second gate stack structure GST_B to directly contact the second source layer SR_B, and may be connected to the second bit line BL_B via a second bit line contact BCT_B.

Each of the first bit line contact BCT_A and the second bit line contact BCT_B may pass through the fourth insulating layer (IL4_A or IL4_B) which is disposed between the bit line BL_A or BL_B and the gate stack structure GST_A or GST_B. The fourth insulating layer may include a lower fourth insulating layer IL4_A of the first structure ST1 and an upper fourth insulating layer IL4_B of the second structure ST2. The lower fourth insulating layer IL4_A may extend between the first gate stack structure GST_A and the first common source structure CS_A. The upper fourth insulating layer IL4_B may extend between the second gate stack structure GST_B and the second common source structure CS_B. The first dummy channel pillar DCH_A may pass through the first gate stack structure GST_A to directly contact the first source layer SR_A and be insulated from the first common source structure CS_A by the lower fourth insulating layer IL4_A. The second dummy channel pillar DCH_B may pass through the second gate stack structure GST_B to directly contact the second source layer SR_B and be insulated from the second common source structure CS_B by the upper fourth insulating layer IL4_B.

The first bit line BL_A may include one side toward the first gate stack structure GST_A and the other side opposite to the one side. The other side of the first bit line BL_A may be covered by a fifth insulating layer IL5. The fifth insulating layer IL5 may include at least two insulating layers. Cell-side bonding patterns CBP may be disposed in the fifth insulating layer IL5.

The cell-side bonding patterns CBP may be bonded to peripheral circuit-side bonding patterns PBP of the peripheral circuit 40. Each of the cell-side bonding patterns CBP and the peripheral circuit-side bonding patterns PBP may include bonding metals such as copper, aluminum, and tungsten.

The peripheral circuit 40 may include the first transistor TR1 and the second transistor TR2. The first transistor TR1 may include the page buffer 37 as shown in FIG. 1. The second transistor TR2 may be included in the source driver 39 as shown in FIG. 1.

The first transistor TR1 and the second transistor TR2 may be covered by a peripheral circuit insulating structure PIL between a semiconductor substrate SUB and the fifth insulating layer IL5. The first transistor TR1 and the second transistor TR2 may be arranged in active regions of the semiconductor substrate SUB divided by isolation layers ISO.

As described above with reference to FIGS. 4A and 4B, each of the first transistor TR1 and the second transistor TR2 may include the gate insulating layer GI1 or GI2, the gate electrode GE1 or GE2, the first junction JN11 or JN21, and the second junction JN21 or JN22. The first transistor TR1 and the second transistor TR2 may be coupled to interconnections IC disposed in the peripheral circuit insulating structure PIL. Some of the interconnections IC may be used to couple the junction JN12 of the first transistor TR1 to one of the cell-side bonding patterns CBP, and other interconnections IC may be used to couple the junction JN22 of the second transistor TR2 to another cell-side bonding pattern CBP2.

The plurality of first source layers SR_A may be separated from the plurality of second source layers SR_B by sixth insulating layers (IL6A and IL6B). The sixth insulating layers may include a lower sixth insulating layer IL6A of the first structure ST1 and an upper sixth insulating layer IL6B of the second structure ST2. The lower sixth insulating layer IL6A and the upper sixth insulating layer IL6B may be bonded to each other.

Referring to FIGS. 8, 9A, and 9B, the first isolation structure SS_A of the first structure ST1 may be disposed between neighboring first gate stack structures GST_A. The second isolation structure SS_B of the second structure ST2 may be disposed between neighboring second gate stack structures GST_B. Each of the first isolation structure SS_A and the second isolation structure SS_B may extend in the second direction DR2.

Each of the first isolation structure SS_A and the second isolation structure SS_B may include a plurality of first insulating structures and a plurality of second insulating structures SS2A or SS2B. Although FIGS. 9A and 9B do not illustrate the plurality of first insulating structures, the plurality of first insulating structures of each of the first and second isolation structures SS_A and SS_B may be spaced apart from each other in the second direction DR2 to form rows as in the plurality of first insulating structures SS1 shown in FIG. 5A or the plurality of first insulating structures SS1 shown in FIG. 7. Each of the second insulating structures SSA2A and SS2B may be disposed between neighboring first insulating structures in the second direction DR2. Some of the plurality of second insulating structures SS2A of the first isolation structure SS_A may be disposed between the first cell array regions CR1 of the first gate stack structures GST_A, and other second insulating structures SS2A may be disposed between the first dummy cell array regions DCR1 of the first gate stack structures GST_A. Some of the plurality of second insulating structures SS2B of the second isolation structure SS_B may be disposed between the second cell array regions CR2 of the second gate stack structures GST_B, and other second insulating structures SS2B may be disposed between the second dummy cell array regions DCR2 of the second gate stack structures GST_B. Hereinafter, for convenience of explanation, the second insulating structure SS2A of the first isolation structure SS_A is referred to as a lower insulating structure, and the second insulating structure SS2B of the second isolation structure SS_B is referred to as an upper insulating structure.

A first source isolation insulating layer SIL_A may be disposed between neighboring first source layers SR_A, and a second source isolation insulating layer SIL_B may be disposed between neighboring second source layers SR_B in the first direction DR1. The first source isolation insulating layer SIL_A may overlap the first isolation structure SS_A and the second source isolation insulating layer SIL_B may overlap the second isolation structure SS_B.

Referring to FIG. 9A, one pair of the first bit line BL_A and the second bit line BL_B may be coupled to each other by the first conductive via structure V1. The first conductive via structure V1 may include a first portion V1A and a second portion V1B. The first portion V1A may be associated with the first structure ST1 and the second portion V1B may be associated with the second structure ST2. Each of the first portion V1A and the second portion V1B may include a first contact pattern C1A or C1B, a second contact pattern C2A or C2B, and a third contact pattern C3A or C3B.

At the first portion V1A of the first conductive via structure V1, the first contact pattern C1A may include a conductive material which is disposed between the first gate stack structures GST_A, the second contact pattern C2A may include a conductive material which passes through the lower fourth insulating layer IL4_A, and the third contact pattern C3A may include a conductive material which passes through the first source isolation insulating layer SIL_A and the lower sixth insulating layer IL6A. The first contact pattern C1A may be aligned with the second contact pattern C2A in the third direction DR3 and be coupled to the second contact pattern C2A. The third contact pattern C3A may be aligned with the first contact pattern C1A in the third direction DR3 and be coupled to the first contact pattern C1A. A lower insulating structure which is disposed between the first cell array regions CR1 of the first gate stack structures GST_A, among the lower insulating structures SS2A, may surround a side wall of the first contact pattern C1A.

At the second portion V1B of the first conductive via structure V1, the first contact pattern C1B may include a conductive material which is disposed between the second gate stack structures GST_B, the second contact pattern C2B may include a conductive material which passes through the upper fourth insulating layer IL4_B, and the third contact pattern C3A may include a conductive material which passes through the second source isolation insulating layer SIL_B and the upper sixth insulating layer IL6B. The first contact pattern C1B may be aligned with the third contact pattern C3B in the third direction DR3 and be coupled to the third contact pattern C3B. The second contact pattern C2B may be aligned with the first contact pattern C1B in the third direction DR3 and be coupled to the first contact pattern C1B. An upper insulating structure which is disposed between the second cell array regions CR2 of the second gate stack structures GST_B, among the upper insulating structures SS2B, may surround a side wall of the first contact pattern C1B.

In the first conductive via structure V1, the third contact pattern C3A of the first portion V1A and the third contact pattern C3B of the second portion V1B may be bonded to each other. The third contact pattern C3A of the first portion V1A and the third contact pattern C3B of the second portion V1B may include bonding metals such as copper, aluminum, and tungsten.

One pair of the first bit line BL_A and the second bit line BL_B which are coupled to each other by the first conductive via structure V1 may be electrically coupled to the second junction JN12 of the first transistor TR1 by the interconnections IC, the peripheral circuit-side bonding pattern PBP, and the cell-side bonding pattern CBP.

Referring to FIG. 9B, the first common source structure CS_A and the second common source structure CS_B may be coupled to each other by the second conductive via structure V2. The second conductive via structure V2 may include a first source contact portion V2A and a second source contact portion V2B. The first source contact portion V2A may be associated with the first structure ST1 and the second source contact portion V2B may be associated with the second structure ST2. Each of the first source contact portion V2A and the second source contact portion V2B may include a first source contact pattern C1A′ or C1B′, a second source contact pattern C2A′ or C2B′, and a third source contact pattern C3A′ or C3B′.

At the first source contact portion V2A of the second conductive via structure V2, the first source contact pattern C1A′ may include a conductive material which is disposed between the first gate stack structures GST_A, the second contact pattern C2A′ may include a conductive material which passes through the lower fourth insulating layer IL4_A, and the third contact pattern C3A′ may include a conductive material which is disposed between neighboring first source layers SR_A in the first direction DR1. The first source contact pattern C1A′ may be aligned with the second source contact pattern C2A′ in the third direction DR3 and coupled to the second source contact pattern C2A′. The third source contact pattern C3A′ may be aligned with the third source contact pattern C3A′ in the third direction DR3 and coupled to the third source contact pattern C3A′. A lower insulating structure which is disposed between the first dummy cell array regions DCR1 of the first gate stack structures GST_A among the lower insulating structures (see the second insulating structures SS2A of the first isolation structure SS_A) may surround a side wall of the first source contact pattern C1A′. The first source layer SR_A may contact a side wall of the third source contact pattern C3A′. The third source contact pattern C3A′ may pass through the lower sixth insulating layer IL6A.

At the second source contact portion V2B of the second conductive via structure V2, the first source contact pattern C1B′ may include a conductive material which is disposed between the second gate stack structures GST_B, the second source contact pattern C2B′ may include a conductive material which passes through the fourth insulating layer IL4_B of the second gate stack structure ST2, and the third source contact pattern C3B′ may include a conductive material which is disposed between neighboring second source layers SR_B in the first direction DR1. The first source contact pattern C1B′ may be aligned with the third source contact pattern C3B′ in the third direction DR3 and coupled to the third source contact pattern C3B′. The second source contact pattern C2B′ may be aligned with the first source contact pattern C1B′ in the third direction DR3 and coupled to the first source contact pattern C1B′. An upper insulating structure which is disposed between the second dummy cell array regions DCR2 of the second gate stack structures GST_B among the upper insulating structures (see the second insulating structures SS2B of the second isolation structure SS_B) may surround a side wall of the first source contact pattern C1B′. The second source layer SR_B may contact a side wall of the third source contact pattern C3B′. The third source contact pattern C3B′ may pass through the upper sixth insulating layer IL6B.

In the second conductive via structure V2, the third contact pattern C3A′ of the first source contact portion V2A and the third source contact pattern C3B′ of the second source contact portion V2B may be bonded to each other. The third source contact pattern C3A′ of the first source contact portion V2A and the third source contact pattern C3B′ of the second source contact portion V2B may include bonding metals such as copper, aluminum, and tungsten.

The first common source structure CS_A and the second common source structure CS_B which are coupled to each other by the second conductive via structure V2 may be electrically coupled to the second junction JN22 of the second transistor TR2 by the interconnections IC, the peripheral circuit-side bonding pattern PBP, and the cell-side bonding pattern CBP.

As described above with reference to FIGS. 8, 9A, and 9B, the first bit line BL_A connected to the first memory cell array 10A and the second bit line BL_B connected to the second memory cell array 10B may be connected to each other by the first conductive via structure V1. The first conductive via structure V1 may extend from between neighboring first gate stack structures GST_A to between neighboring second gate stack structures GST_B. As a result, in an embodiment, a degree of integration of the semiconductor memory device may be increased since a separate area might not be provided for the first conductive via structure V1 for coupling the first bit line BL_A and the second bit line BL_B to each other. In addition, in an embodiment, by coupling one of the first and second bit lines BL_A and BL_B to the first transistor TR1, one pair of the first bit line BL_A and the second bit line BL_B may be controlled by the first transistor TR1, so that the connection structure between each of the first bit line BL_A and the second bit line BL_B and the page buffer. As a result, in an embodiment, structural defects occurring during manufacturing processes of the semiconductor memory device may be reduced.

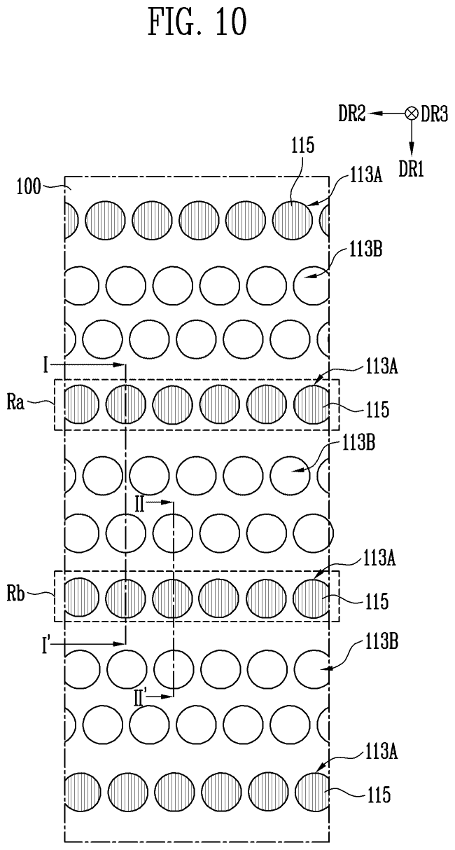

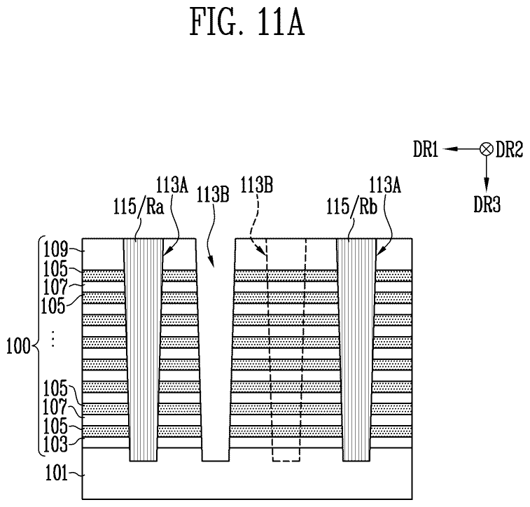

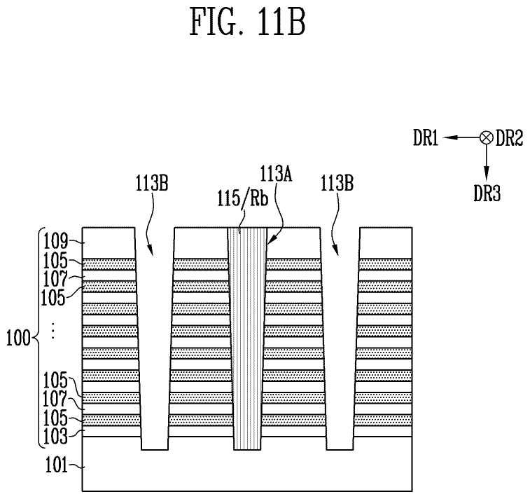

FIGS. 10, 12, 14, 16, and 19 are plan views illustrating manufacturing processes for providing a semiconductor memory device according to an embodiment of the present disclosure. FIGS. 11A, 11B, 13A, 13B, 15A, 15B, 17, 18A, 18B, 20A, 20B, 21A, 21B, 21C, 21D, 21E, and 21F are cross-sectional diagrams illustrating manufacturing processes for providing a semiconductor memory device according to an embodiment of the present disclosure.

FIG. 10 is a plan view illustrating processes for forming a plurality of openings 113A and 113B and a plurality of sacrificial pillars 115 in a stack 100. FIG. 11A is a cross-sectional view of the stack 100 taken along line I-I′ of FIG. 10. FIG. 11B is a cross-sectional view of the stack 100 taken along line II-II′ shown in FIG. 10.

Referring to FIGS. 10, 11A, and 11B, the stack 100 may be formed over a substrate 101. The substrate 101 may include a silicon wafer. The substrate 101 may include an upper surface which extends in the first direction DR1 and the second direction DR2 crossing each other. The stack 100 may include a first insulating layer 103, a plurality of sacrificial layers 105, a plurality of second insulating layers 107, and a third insulating layer 109 which are disposed over the substrate 101.

Each of the first insulating layer 103, the plurality of second insulating layers 107, and the third insulating layer 109 may include an insulating material such as a silicon oxide layer and a silicon oxynitride layer. The plurality of sacrificial layers 105 may include a material having a different etch rate from that of each of the first insulating layer 103, the plurality of second insulating layers 107, and the third insulating layer 109. According to an embodiment, the plurality of sacrificial layers 105 may include a sacrificial insulating material such as a silicon nitride. The sacrificial layers 105 and the second insulating layers 107 may be arranged alternately with each other in the third direction DR3 between the first insulating layer 103 and the third insulating layer 109. The third direction DR3 may be perpendicular to a top surface of the substrate 101.

Subsequently, the plurality of openings (113A and 113B) may be formed through the stack 100. Each of the plurality of openings 113A may extend into the substrate 101. The plurality of openings may include a plurality of first openings 113A and a plurality of second openings 113B. The plurality of first openings 113A may be arranged in a plurality of rows, and the first openings 113A in each row may be arranged next to each other in the second direction DR2. The plurality of second openings 113B may be disposed between the first openings 113A which are spaced apart from each other in the first direction DR1. According to an embodiment, the plurality of first openings 113A may include first openings in a first row Ra and first openings in a second row Rb separated from the first row Ra. The plurality of second openings 113B may be disposed between the first row Ra and the second row Rb and form at least one row.

Subsequently, each of the plurality of first openings 113A and the plurality of second openings 113B may be filled with a sacrificial layer. The sacrificial layer may include a titanium nitride (TiN) and carbon. Subsequently, the plurality of second openings 113B may be exposed by removing the sacrificial layer from the plurality of second openings 113B by using a mask process and an etch process. The remaining sacrificial layer may form a plurality of sacrificial pillars 115 in the plurality of first openings 113A.

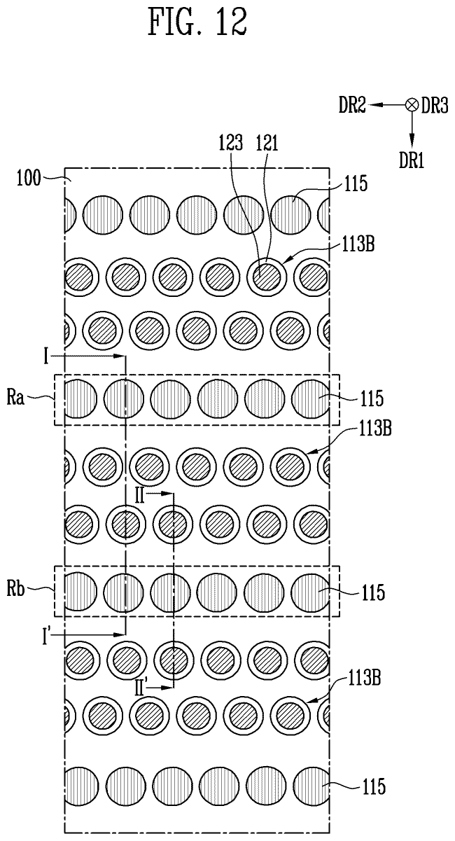

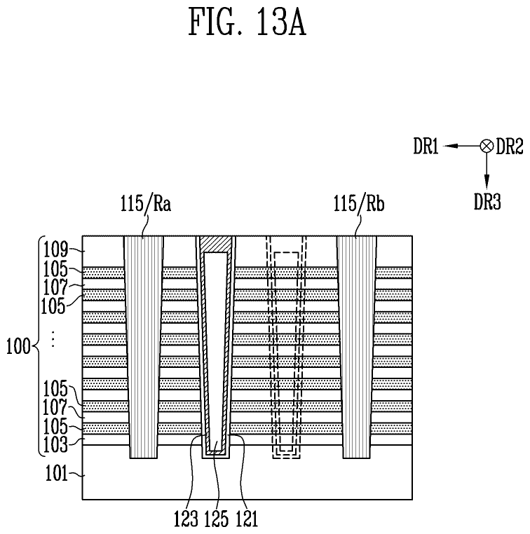

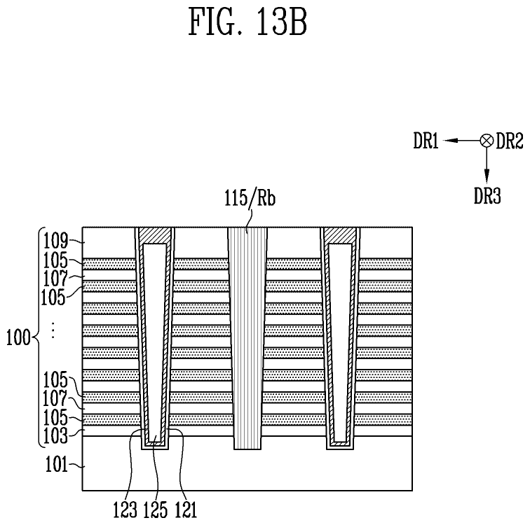

FIG. 12 is a plan view illustrating processes of filing the plurality of second openings 113B. FIG. 13A is a cross-sectional view of the stack 100 taken along line I-I′ of FIG. 12. FIG. 13B is a cross-sectional view of the stack 100 taken along line II-II′ of FIG. 12.

Referring to FIGS. 12, 13A, and 13B, a memory layer 121 may be formed on an inner wall of each of the second openings 113B. The memory layer 121 may include the blocking insulating layer BI, the data storage layer DS, and the tunnel isolation layer TI as shown in FIG. 5B. A channel pillar 123 and a core insulating layer 125 may be formed in a central area of the second opening 113B which is opened by the memory layer 121.

According to an embodiment, the processes of forming the channel pillar 123 and the core insulating layer 125 may include a process of forming a channel layer on an inner wall of the memory layer 121 and a process of filling a central area of a tubular structure defined by the channel layer with the core insulating layer 125 and a capping pattern. The channel layer may include a semiconductor material such as silicon (Si), germanium (Ge), or a mixture thereof which serves as a channel region. The capping pattern may include a doped semiconductor layer. The channel layer and the capping pattern may form the channel pillar 123.

Though not shown, the dummy memory layer, the dummy channel pillar, and the dummy core insulating layer as described above with reference to FIGS. 9A and 9B may be formed using the processes of forming the channel pillar 121, the channel pillar 123, and the core insulating layer 125.

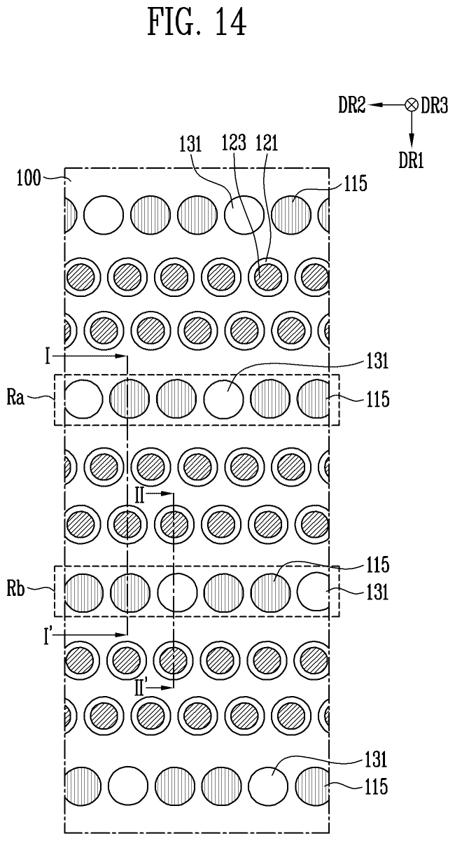

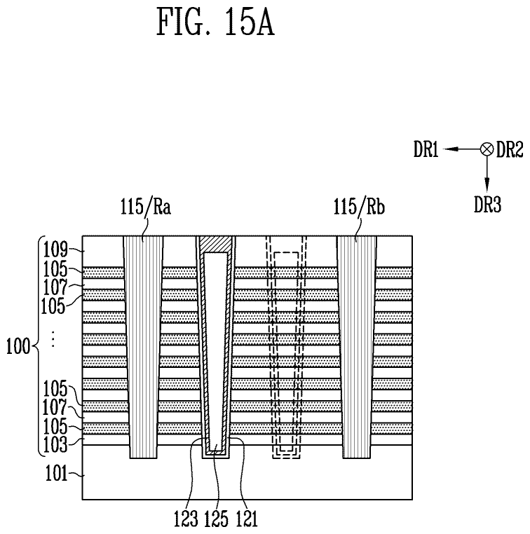

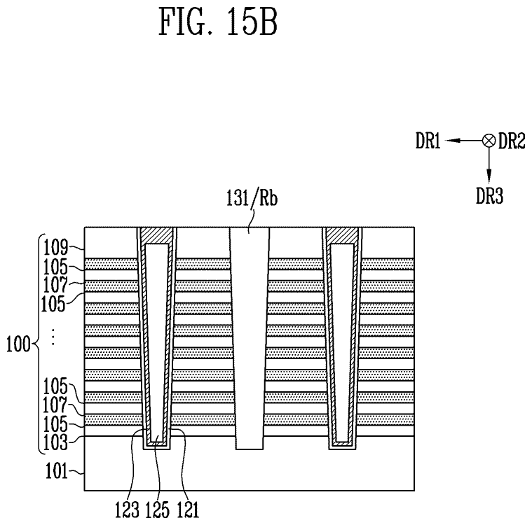

FIG. 14 is a plan view illustrating processes of forming the plurality of first insulating structures 131. FIG. 15A is a cross-sectional view of the stack 100 taken along line I-I′ shown in FIG. 14. FIG. 15B is a cross-sectional view of the stack 100 taken along line II-II′ shown in FIG. 14.

Referring to FIGS. 14, 15A, and 15B, some of the sacrificial pillars 115 may be replaced by the first insulating structures 131. To this end, some of the plurality of sacrificial pillars 115 may be removed, and each of the regions from which the sacrificial pillars 115 may be filled with an insulating material.

In each row, the first insulating structures 131 may be spaced apart from each other in the second direction DR2 with at least two sacrificial pillars 115 arranged in the second direction DR2. According to an embodiment, referring to the first row Ra, two sacrificial pillars 115 arranged in the second direction DR2 may be disposed between the first insulating structures 131 separated from each other in the second direction DR2.

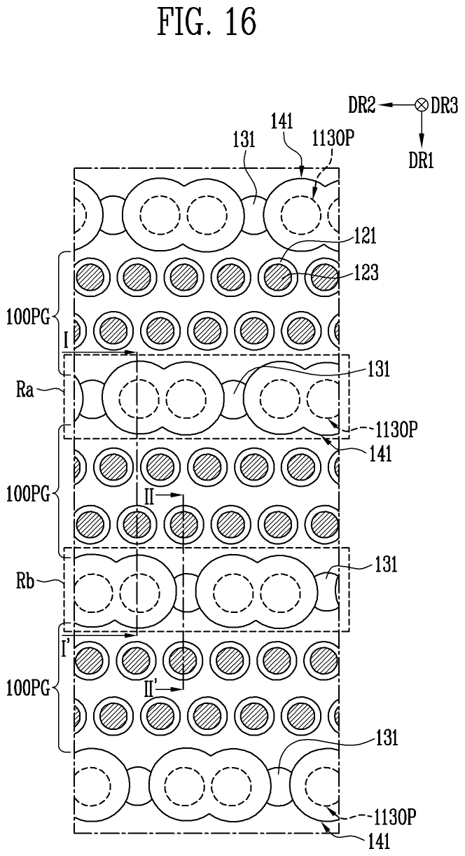

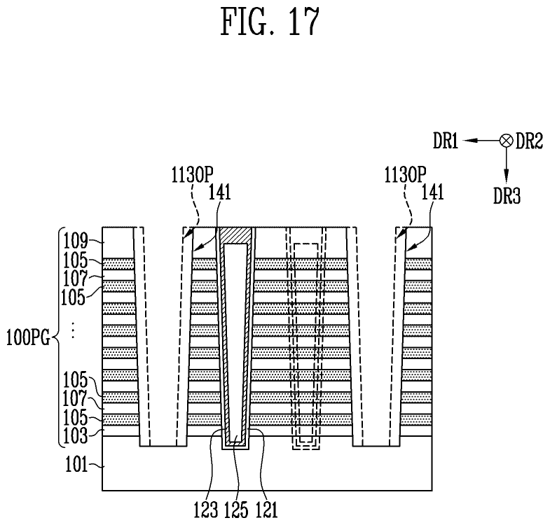

FIG. 16 is a plan view illustrating processes of separating a plurality of preliminary gate stack structures 100PG from each other. FIG. 17 is a cross-sectional view of the preliminary gate stack structures 100PG taken along line I-I′ shown in FIG. 16.

Referring to FIGS. 16 and 17, a plurality of third openings 1130P may be defined by removing the plurality of sacrificial pillars 115 shown in FIGS. 14, 15A, and 15B. The plurality of third openings 1130P and the plurality of first insulating structures 131 may form a plurality of rows.

Subsequently, each of the first insulating layer 103, the plurality of sacrificial pillars 105, the plurality of second insulating layers 107, and the third insulating layer 109 may be partially etched such that neighboring third openings 1130P in the second direction DR2 in each row may be coupled to each other. As a result, a plurality of fourth openings 141 may be formed. Each of the fourth openings 141 may be defined by the third openings 1130P coupled to each other.

A side wall of each of the plurality of first insulating structures 131 may be partially exposed by the plurality of fourth openings 141. Each of the plurality of first insulating structures 131 may be partially exposed by the plurality of fourth openings 141.

The plurality of fourth openings 141 and the plurality of first insulating structures 131 may form a plurality of rows. In each row, the fourth opening 141 may be disposed between neighboring first insulating structures 131 in the second direction DR2. For example, referring to the first row Ra, the first insulating structure 131 and the fourth opening 141 may be disposed alternately with each other in the second direction DR2 and may be coupled to each other, and the fourth opening 141 may be disposed between neighboring first insulating structures 131 in the second direction DR2.

The stack 100 may be separated into the plurality of preliminary gate stack structures 100PG by the plurality of first insulating structures 131 and the plurality of fourth openings 141.

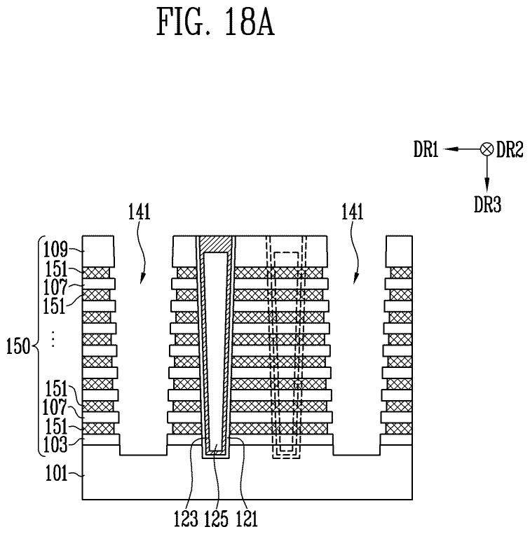

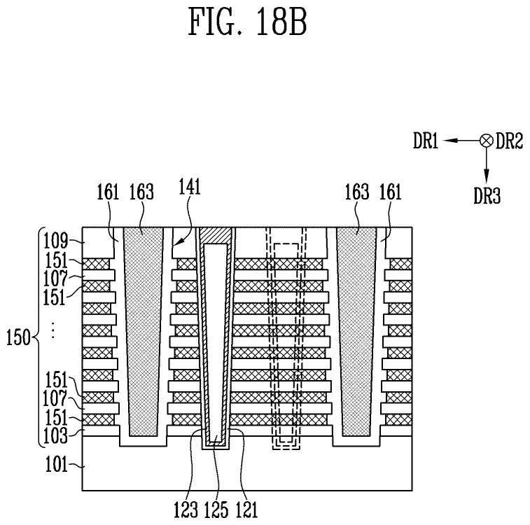

FIGS. 18A and 18B are cross-sectional views for illustrating processes performed after the processes of separating the plurality of preliminary gate stack structures are performed. FIGS. 18A and 18B show a cross section of a gate stack structure 150 taken along line I-I′ of FIG. 16.

Referring to FIG. 18A, the plurality of sacrificial layers 105 of each of the preliminary gate stack structures 100PG as shown in FIG. 17 may be selectively removed through the plurality of fourth openings 141. Subsequently, a plurality of conductive layers 151 may be formed in areas from which the plurality of sacrificial layers are removed. As a result, the gate stack structure 150 which includes the first insulating layer 103, the plurality of conductive layers 151, the plurality of second insulating layers 107, and the third insulating layer 109 may be formed.

In an embodiment, the plurality of first insulating structures 131 and the channel pillars 123 as shown in FIG. 16 may serve as a support structure for preventing or mitigating distortion of space between the first insulating layer 103, the plurality of second insulating layers 107, and the third insulating layer 109 before the plurality of conductive layers 151 are formed after the plurality of sacrificial layers are removed.

Referring to FIG. 18B, an insulating layer may be deposited onto a surface of each of the plurality of fourth openings 141. As a result, a plurality of second insulating structures 161 may be formed in the plurality of fourth openings 141.

Subsequently, a central area of each of the plurality of fourth openings 141 may be filled with a conductive material. As a result, a plurality of first contact patterns 163 may be formed in the plurality of fourth openings 141. According to an embodiment, each of the first contact patterns 163 may be self-aligned in the central area of a corresponding one of the fourth openings 141. Accordingly, in an embodiment, misalignment errors in the plurality of first contact patterns 163 may be prevented or reduced. The plurality of first contact patterns 163 may be insulated from the plurality of conductive layers 151 by the plurality of second insulating structures 161 and the plurality of first insulating structures 131 shown in FIG. 16.

The first source contact pattern C1A′ or C1B′ as shown in FIG. 9B may be formed using the processes of forming the plurality of first contact patterns 163.

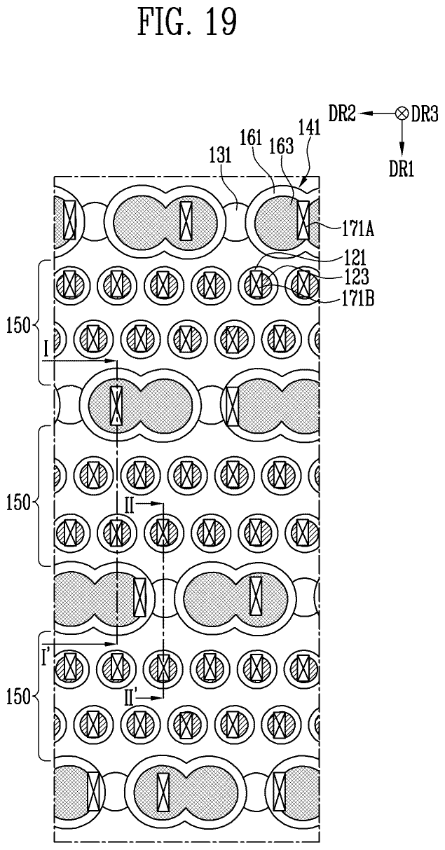

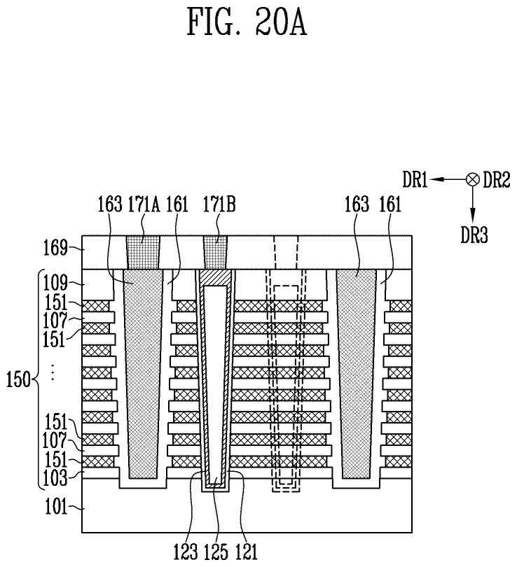

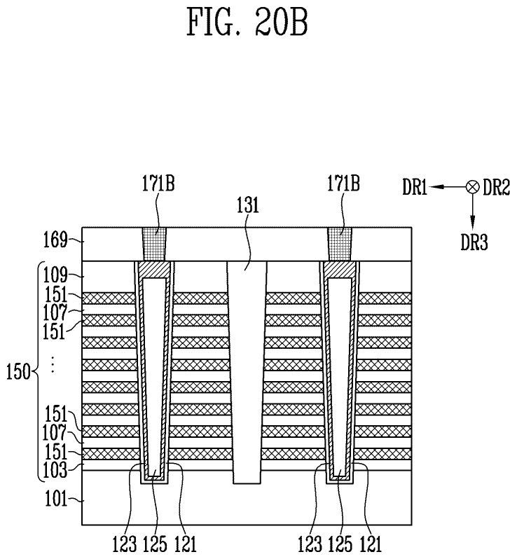

FIG. 19 is a plan view illustrating subsequent processes after the plurality of first contact patterns 163 are formed. FIG. 20A is a cross-sectional view of the gate stack structure 150 taken along line I-I′ of FIG. 19. FIG. 20B is a cross-sectional view of the gate stack structure 150 taken along line II-II′ shown in FIG. 19.

Referring to FIGS. 19, 20A, and 20B, a fourth insulating layer 169 may be formed over the plurality of gate stack structures 150. The fourth insulating layer 169 may extend in the first direction DR1 and the second direction DR2 to cover the plurality of first contact patterns 163, the plurality of first insulating structures 131, and the channel pillar 123.

Subsequently, a plurality of second contact patterns 171A and a bit line contact 171B may be formed through the fourth insulating layer 169. The plurality of second contact patterns 171A may be coupled to the plurality of first contact patterns 163, respectively. The bit line contact 171B may be coupled to the channel pillar 123.

The second source contact pattern C2A′ or C2B′ shown in FIG. 9B may be formed using the processes of forming the plurality of second contact patterns 171A.

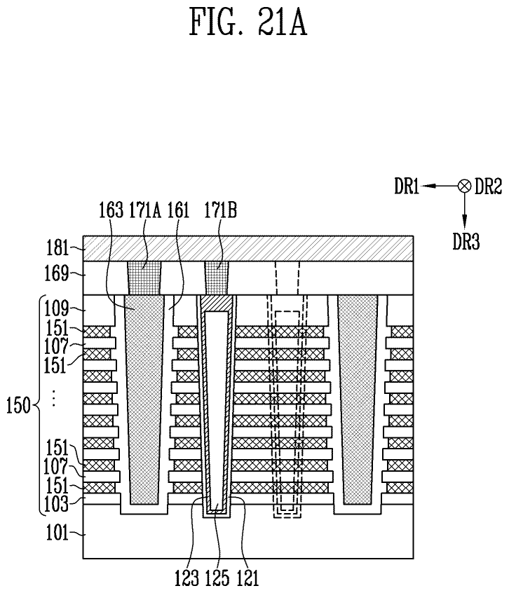

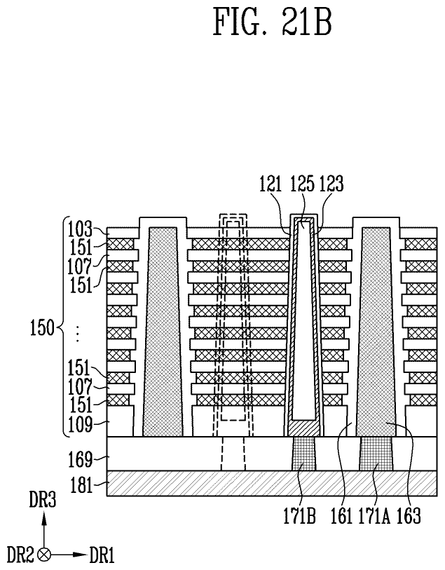

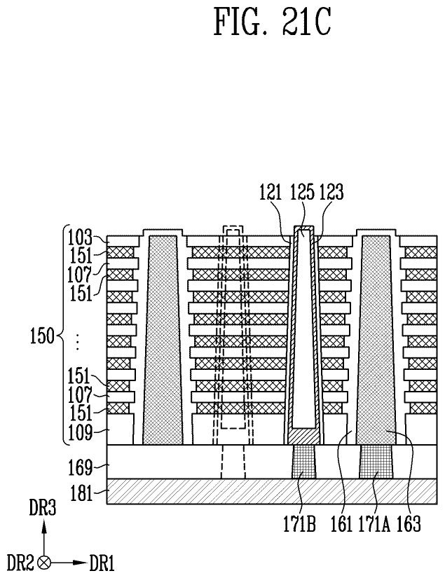

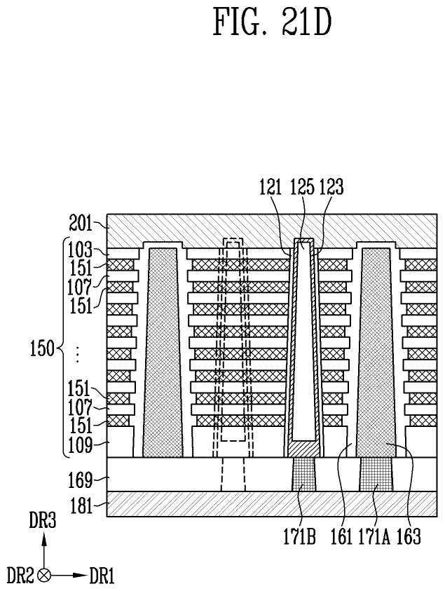

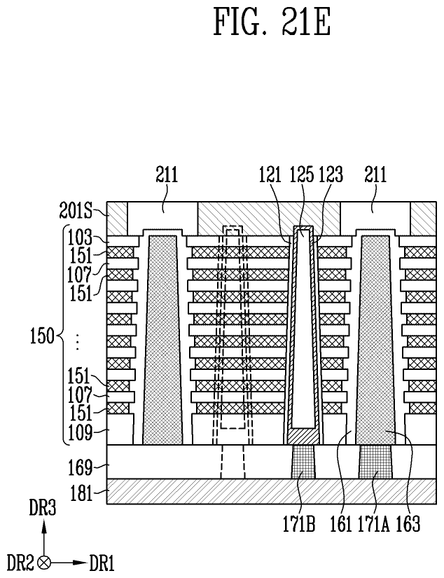

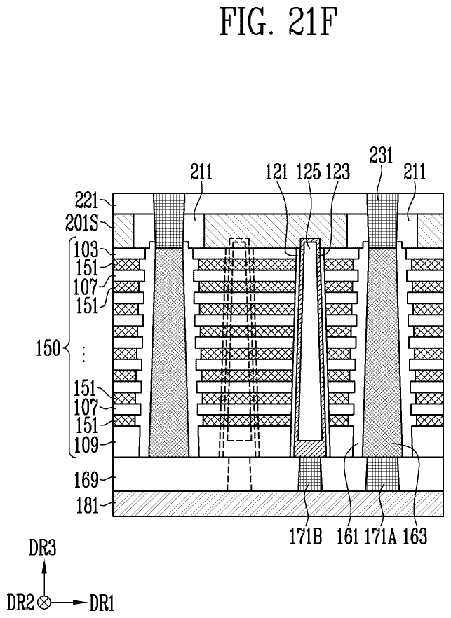

FIGS. 21A to 21F are cross-sectional views illustrating processes performed after the plurality of second contact patterns 171A and the bit line contact 171B are formed. FIGS. 21A to 21F show a cross section of the gate stack structure 150 taken along line I-I′ of FIG. 19.

Referring to FIG. 21A, a plurality of bit lines 181 may be formed over the fourth insulating layer 169. The plurality of bit lines 181 may extend in the first direction DR1 and be spaced apart from each other in the second direction DR2.

The first common source structure CS_A or the second common source structure CS_B shown in FIGS. 8, 9A, and 9B may be formed using the processes of forming the plurality of bit lines 181.

Referring to FIG. 21B, the substrate 101 shown in FIG. 21A may be removed. As a result, the second insulating structure 161 and the memory layer 121 may be exposed.

Though not shown, various processes may be additionally performed before the substrate 101 shown in FIG. 21A is removed.

According to an embodiment, before the substrate 101 shown in FIG. 21A is removed, the fifth insulating layer IL5 and the first cell-side bonding patterns CBP1 shown in FIGS. 4A and 4B may be formed, and the first sub-peripheral circuit 40A shown in FIGS. 4A and 4B may be provided. As shown in FIGS. 4A and 4B, the first cell-side bonding pattern CBP1 may be bonded to the first peripheral circuit-side bonding pattern PBP1 of the first sub-peripheral circuit 40A. After bonding, the substrate 101 shown in FIG. 21A may be removed.

In another embodiment, before the substrate 101 shown in FIG. 21A is removed, the fifth insulating layer IL5 and the cell-side bonding patterns CBP shown in FIGS. 9A and 9B may be formed, and the peripheral circuit 40 shown in FIGS. 9A and 9B may be provided. As shown in FIGS. 9A and 9B, the cell-side bonding pattern CBP may be bonded to the peripheral circuit-side bonding pattern PBP of the peripheral circuit 40. After bonding, the substrate 101 shown in FIG. 21A may be removed.

Referring to FIG. 21C, the exposed portion of each second insulating structure 161 and the exposed portion of the memory layer 121 may be selectively removed. The memory layer 121 may be etched to expose an end portion of the channel pillar 123. Because the second insulating structure 161 is thicker than the memory layer 121, although the second insulating structure 161 is partially etched while the memory layer 121 is removed, another portion of the second insulating structure 161 may remain to cover an end portion of each of the plurality of first contact patterns 163.

Referring to FIG. 21D, the exposed portion of the channel pillar 123 may be covered by a doped semiconductor layer 201. The doped semiconductor layer 201 may extend to cover the plurality of second insulating structures 161. Each of the first contact patterns 163 may be separated from the doped semiconductor layer 201 by the second insulating structure 161.

Referring to FIG. 21E, a portion of the doped semiconductor layer 201 may be etched such that the doped semiconductor layer 201 shown in FIG. 21D may be separated into a plurality of source layers 201S. The plurality of source layers 201S may overlap the plurality of gate stack structures 150, respectively. The plurality of source layers 201S may be patterned such that a corresponding one of the first contact patterns 163 may be disposed between neighboring source layers 201S.

Subsequently, an area from which the doped semiconductor layer is etched may be filled with an insulating material. As a result, a plurality of source isolation insulating layers 211 may be formed. Each of the source isolation insulating layers 211 may be disposed between neighboring source layers 201S and extend in the second direction DR2. The plurality of source isolation insulating layers 211 may overlap the plurality of second insulating structures 161 and the plurality of first contact patterns 163.

Referring to FIG. 21F, a sixth insulating layer 211 may be formed to cover the plurality of source layers 201S. Subsequently, a plurality of third contact patterns 231 may be formed through the sixth insulating layer 221, the plurality of source isolation insulating layers 211, the plurality of second insulating structures 161. Each of the third contact patterns 231 may overlap a corresponding one of the first contact patterns 163 and be coupled to the third contact pattern 163.

The third source contact pattern C3A′ or C3B′ shown in FIG. 9B may be formed using the processes of forming the plurality of third contact patterns 231.

Though not shown, subsequent processes may be performed in various manners.

According to an embodiment, after the third contact pattern 231 is formed, a process of forming the second conductive via structure V2 shown in FIGS. 4A and 4B, the process of forming the common source structure CS shown in FIGS. 4A and 4B, and the process of forming the seventh insulating layer IL7 and the second cell-side bonding patterns CBP2 shown in FIGS. 4A and 4B may be performed. The second sub-peripheral circuit 40B shown in FIGS. 4A and 4B may be separately provided. After the second cell-side bonding pattern shown in FIGS. 4A and 4B is formed, the second peripheral circuit-side bonding pattern PBP2 of the second sub-peripheral circuit 40B may be bonded to the second cell-side bonding pattern CBP2.

In another embodiment, the second structure described above with reference to FIGS. 9A and 9B may be provided through a separate process. After the third contact pattern 231 is formed, the second structure may be bonded to the third contact pattern 231 and the sixth insulating layer 221.

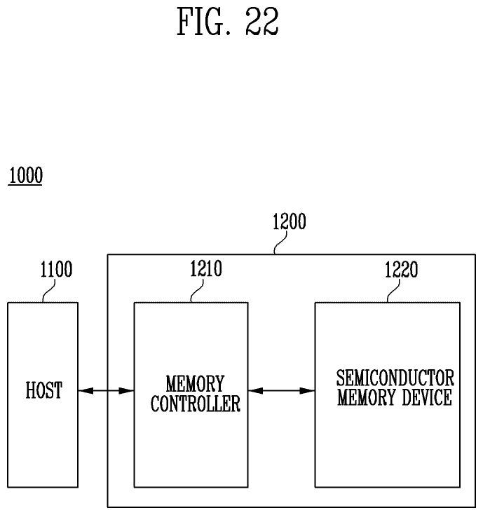

FIG. 22 is a block diagram illustrating an electronic system 1000 according to an embodiment of the present disclosure.

Referring to FIG. 22, the electronic system 1000 may include a computing system, a medical device, a communication device, a wearable device, or a memory system. The electronic system 1000 may include a host 1100 and a storage device 1200.

The host 1100 may store data in the storage device 1200, or may read the stored data from the storage device 1200 on the basis of an interface. The interface may include at least one of a Double Data Rate (DDR) interface, a Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics interface (IDE), a Firewire interface, a Universal Flash Storage (UFS) interface, and a Nonvolatile Memory express (NVMe) interface.

The storage device 1200 may include a memory controller 1210 and a semiconductor memory device 1220. According to an embodiment, the storage device 1200 may be a solid state drive (SSD), a universal serial bus (USB) memory, or the like.

The memory controller 1210 may store data in the semiconductor memory device 1220, or may read data stored in the semiconductor memory device 1220 in response to control of the host 1100.

The semiconductor memory device 1220 may include a single memory chip or a plurality of memory chips. The semiconductor memory device 1220 may store data or output stored data in response to control of the memory controller 1210.

The semiconductor memory device 1220 may be a non-volatile memory device. The semiconductor memory device 1220 may include a plurality of gate stack structures penetrated by a plurality of channel pillars, a conductive via structure disposed between neighboring gate stack structures, and a bit line coupled to the conductive via structure.

According to an embodiment of the present disclosure, the structure of a semiconductor memory device may be simplified by arranging a conductive via structure coupled to a bit line between neighboring gate stack structures. Accordingly, in an embodiment, structural defects occurring during processes of manufacturing the semiconductor memory device may be reduced, so that the operational reliability of the semiconductor memory device may be improved.

It will be apparent to those skilled in the art that various modifications can be made to the above-described embodiments without departing from the spirit or scope of the disclosure. Thus, it is intended that the present disclosure cover all such modifications provided they come within the scope of the appended claims and their equivalents.

What is claimed is:

1. A semiconductor memory device, comprising:
a bit line array including a plurality of bit lines extending in a first direction;
a plurality of source layers extending in a second direction crossing the plurality of bit lines, the plurality of source layers overlapping with the plurality of bit lines;
a plurality of gate stack structures arranged in the first direction, the plurality of gate stack structures each including a plurality of conductive layers stacked and spaced apart from each other in a third direction, the third direction toward the plurality of source layers and away from the bit line array;
a plurality of channel pillars extending in the third direction to pass through, respectively, the plurality of gate stack structures;
a memory layer extending on a side wall of each of the plurality of channel pillars, respectively;
an isolation structure disposed between neighboring gate stack structures among the plurality of gate stack structures, the isolation structure extending in the second direction; and
a first conductive via structure disposed in the isolation structure, the first conductive via coupled to a corresponding bit line among the plurality of bit lines.

2. The semiconductor memory device of claim 1, wherein:
each of the plurality of gate stack structures corresponds to each of the plurality of source layers, and
each of the plurality of gate stack structures is disposed between the bit line array and a corresponding source layer among the plurality of source layers.

3. The semiconductor memory device of claim 1, further comprising a source isolation insulating layer disposed between neighboring source layers among the plurality of source layers, overlapping the isolation structure, and penetrated by the first conductive via structure.

4. The semiconductor memory device of claim 1, wherein the isolation structure comprises:
a plurality of first insulating structures spaced apart from each other in the second direction; and
a second insulating structure disposed between neighboring first insulating structures among the plurality of first insulating structures and surrounding a side wall of the first conductive via structure.

5. The semiconductor memory device of claim 1, further comprising:
an insulating layer covering the plurality of source layers;
a plurality of second conductive via structures passing through the insulating layer and coupled to the plurality of source layers, respectively; and
a common source structure coupled to the plurality of second conductive via structures, respectively, and disposed over the insulating layer.

6. The semiconductor memory device of claim 1, wherein each of the plurality of channel pillars extends into a corresponding source layer among the plurality of source layers to come into contact with the corresponding source layer.

7. The semiconductor memory device of claim 1, further comprising a plurality of bit line contacts coupling the plurality of channel pillars to the bit line array.

8. A semiconductor memory device, comprising:
a first bit line array including a plurality of first bit lines extending in a first direction;
a second bit line array disposed over the first bit line array and including a plurality of second bit lines extending in the first direction;
a plurality of first source layers disposed between the first bit line array and the second bit line array, extending in a second direction crossing the plurality of first bit lines, and arranged in the first direction;
a plurality of second source layers disposed between the plurality of first source layers and the second bit line array, extending in the second direction, and arranged in the first direction;
a first memory cell array disposed between the first bit line array and the plurality of first source layers, the first memory cell array connected to a plurality of first gate stack structures arranged in the first direction;
a second memory cell array disposed between the second bit line array and the plurality of second source layers, the second memory cell array connected to a plurality of second gate stack structures arranged in the first direction; and
a first conductive via structure including a first portion arranged between the plurality of first gate stack structures and a second portion arranged between the plurality of second gate stack structures, and coupling a pair of a first bit line among the plurality of first bit lines and a second bit line among the plurality of second bit lines.

9. The semiconductor memory device of claim 8, wherein the first memory cell array comprises:
a plurality of first channel pillars connected to the first bit line array, passing through the plurality of first gate stack structures, and connected to the plurality of first source layers; and
a first memory layer extending on a side wall of each of the plurality of the first channel pillars, and
wherein the second memory cell array comprises:
a plurality of second channel pillars connected to the second bit line array, passing through the plurality of second gate stack structures, and connected to the plurality of second source layers; and
a second memory layer extending on a side wall of each of the plurality of second channel pillars.

10. The semiconductor memory device of claim 8, further comprising:
a first isolation structure disposed between neighboring first gate stack structures among the plurality of first gate stack structures, extending in the second direction, and surrounding the first portion of the first conductive via structure; and
a second isolation structure disposed between neighboring gate stack structures among the plurality of second gate stack structures, extending in the second direction, and surrounding the second portion of the first conductive via structure.

11. The semiconductor memory device of claim 10, wherein each of the first isolation structure and the second isolation structure comprises:
a plurality of first insulating structures spaced apart from each other in the second direction; and
a second insulating structure disposed between neighboring first insulating structures among the plurality of first insulating structures and surrounding a side wall of the first conductive via structure.

12. The semiconductor memory device of claim 8, further comprising:
a first source isolation insulating layer disposed between neighboring first source layers among the plurality of first source layers and penetrated by the first portion of the first conductive via structure; and
a second source isolation insulating layer disposed between neighboring second source layers among the plurality of second source layers and penetrated by the second portion of the first conductive via structure.

13. The semiconductor memory device of claim 8, further comprising:
a first common source structure spaced apart from the first bit line array in the second direction; and
a second common source structure spaced apart from the second bit line array in the second direction,
wherein the plurality of first source layers and the plurality of second source layers extend to overlap the first common source structure and the second common source structure.

14. The semiconductor memory device of claim 13, further comprising a second conductive via structure including a first source contact portion connected to the first common source structure to extend between the plurality of first source layers and a second source contact portion connected to the second common source structure to extend between the plurality of second source layers,
wherein neighboring first source layers with the first source contact portion interposed therebetween among the plurality of first source layers contact the first source contact portion, and
neighboring second source layers with the second source contact portion interposed therebetween among the plurality of second source layers contact the second source contact portion.

15. The semiconductor memory device of claim 14, wherein the plurality of first gate stack structures and the plurality of second gate stack structures extend to overlap the first common source structure and the second common source structure.

16. The semiconductor memory device of claim 15, further comprising a lower insulating structure disposed between neighboring first gate stack structures among the plurality of first gate stack structures and an upper insulating structure disposed between neighboring second gate stack structures among the plurality of second gate stack structures,
wherein the first source contact portion of the second conductive via structure includes a portion disposed in the lower insulating structure, and
wherein the second source contact portion of the second conductive via structure includes a portion disposed in the upper insulating structure.
